(19) United States
(12) Patent Application Publication
(10) Pub. No.: US 2025/0275310 A1
(43) Pub. Date: Aug. 28, 2025

(54) DISPLAY DEVICE AND ELECTRONIC DEVICE INCLUDING THE SAME

(71) Applicant: Samsung Display Co., LTD., Yongin-si (KR)

(72) Inventors: Chi Hun WON, Yongin-si (KR); Hoo Keun PARK, Yongin-si (KR); Min Woo KIM, Yongin-si (KR); Chae Woo CHUNG, Yongin-si (KR)

(73) Assignee: Samsung Display Co., LTD., Yongin-si (KR)

(21) Appl. No.: 18/958,250

(22) Filed: Nov. 25, 2024

(30) Foreign Application Priority Data
Feb. 22, 2024 (KR) 10-2024-0025968

(51) Int. Cl. H01L 33/40; H01L 25/16; H01L 33/20; H01L 33/38

(52) U.S. Cl. CPC H10H 20/835; H01L 25/167; H10H 20/819; H10H 20/8314

(57) ABSTRACT

A display device includes an anode electrode, a light emitting element disposed on the anode electrode, and a cathode electrode covering at least an upper surface of the light emitting element. The light emitting element includes a bonding electrode electrically connected to the anode electrode, a light emitting stack disposed on the bonding electrode and including a first semiconductor layer, a second semiconductor layer disposed on the first semiconductor layer, and an active layer disposed between the first semiconductor layer and the second semiconductor layer, an insulating layer covering at least a side surface of the active layer, and a reflective electrode layer covering a side surface of the second semiconductor layer which is not covered by the insulating layer, and the reflective electrode layer electrically contacts the cathode electrode.

### CROSS REFERENCE TO RELATED APPLICATION(S)

This application claims priority to and benefits of Korean Patent Application No. 10-2024-0025968 under 35 U.S.C. § 119, filed on Feb. 22, 2024, in the Korean Intellectual Property Office (KIPO), the content of which in its entirety is incorporated herein by reference.

### BACKGROUND

### 1. Technical Field

The disclosure relates to a display device and an electronic device including the display device.

### 2. Description of the Related Art

A display device is a device that displays an image by combining light emitted from a plurality of pixels. In case that efficiency of a pixel is improved, display quality of the display device may be improved.

### SUMMARY

An object of the disclosure is to provide a display device with improved display quality.

According to embodiments of the disclosure, a display device may include an anode electrode, a light emitting element disposed on the anode electrode, and a cathode electrode covering at least an upper surface of the light emitting element. The light emitting element may include a bonding electrode electrically connected to the anode electrode, a light emitting stack disposed on the bonding electrode and including a first semiconductor layer, a second semiconductor layer disposed on the first semiconductor layer, and an active layer disposed between the first semiconductor layer and the second semiconductor layer, an insulating layer covering at least a side surface of the active layer, and a reflective electrode layer covering a side surface of the second semiconductor layer which is not covered by the insulating layer, and the reflective electrode layer electrically contacts the cathode electrode.

In an embodiment, the side surface of the second semiconductor layer which is not covered by the insulating layer may have an inverse taper shape, and a width of the inverse taper shape may gradually increase in a direction away from the anode electrode.

In an embodiment, the second semiconductor layer may include a first area adjacent to the active layer and a second area on the first area, and the reflective electrode layer may cover the side surface of the second semiconductor layer in the second area.

In an embodiment, the insulating layer may cover the side surface of the second semiconductor layer in the first area.

In an embodiment, the second semiconductor layer may include a first doping area, a second doping area, and a third doping area sequentially in a direction away from the anode electrode, and a first average doping concentration in the first doping area may be greater than a second average doping concentration in the second doping area.

In an embodiment, the second average doping concentration in the second doping area may be greater than a third average doping concentration in the third doping area.

In an embodiment, the reflective electrode layer may directly contact at least a portion of the side surface of the second semiconductor layer in the first doping area.

In an embodiment, the reflective electrode layer may not cover an upper surface of the light emitting stack.

In an embodiment, the reflective electrode layer may include at least one selected from a group consisting of aluminum (Al), titanium (Ti), and chromium (Cr).

In an embodiment, the upper surface of the light emitting stack may have a concavo-convex shape.

In an embodiment, the reflective electrode layer may further cover at least a portion of the insulating layer.

According to embodiments of the disclosure, a display device may include an anode electrode, a cathode electrode spaced apart from the anode electrode, and a light emitting element disposed on the anode electrode and the cathode electrode. The light emitting element may include a light emitting stack including a first semiconductor layer, a second semiconductor layer disposed on the first semiconductor layer, and an active layer interposed between the first semiconductor layer and the second semiconductor layer, an insulating layer covering at least a side surface of the active layer, a first bonding electrode electrically connected to each of the first semiconductor layer and the anode electrode, and a second bonding electrode extending from the insulating layer covering a lower surface of the first semiconductor layer, contacting a side surface of the second semiconductor layer which is not covered by the insulating layer, and electrically connected to the cathode electrode.

In an embodiment, the active layer may completely overlap the second semiconductor layer.

In an embodiment, the second semiconductor layer may include a first doping area, a second doping area, and a third doping area sequentially in a direction away from the anode electrode, and a first average doping concentration in the first doping area may be greater than a second average doping concentration in the second doping area.

In an embodiment, the second average doping concentration in the second doping area may be greater than a third average doping concentration in the third doping area.

In an embodiment, the second bonding electrode may directly contact at least a portion of the side surface of the second semiconductor layer in the first doping area.

In an embodiment, the insulating layer may be disposed between the second bonding electrode and the first semiconductor layer.

In an embodiment, an upper surface of the light emitting stack may have a concavo-convex shape.

In an embodiment, the insulating layer may entirely cover a side surface of the first semiconductor layer and the lower surface of the first semiconductor layer, and may define an open portion exposing a portion of the lower surface of the first semiconductor layer, and the first bonding electrode may be electrically connected to the lower surface of the first semiconductor layer through the open portion.

In an embodiment, the first bonding electrode may overlap the anode electrode, and the second bonding electrode may overlap the cathode electrode.

According to embodiments of the disclosure, an electronic device may include a processor to provide input image data, and a display device to display an image based on the input image data. The display device may include an anode electrode, a light emitting element disposed on the anode electrode, and a cathode electrode covering at least an upper surface of the light emitting element. The light emitting element may include a bonding electrode electrically connected to the anode electrode, a light emitting stack disposed on the bonding electrode and including a first semiconductor layer, a second semiconductor layer disposed on the first semiconductor layer, and an active layer disposed between the first semiconductor layer and the second semiconductor layer, an insulating layer covering at least a side surface of the active layer, and a reflective electrode layer covering a side surface of the second semiconductor layer which is not covered by the insulating layer, and the reflective electrode layer electrically contacts the cathode electrode.

A display device according to embodiments of the disclosure may include a light emitting stack including an anode electrode, a cathode electrode, and a light emitting element which includes a first semiconductor layer, a second semiconductor layer disposed on the first semiconductor layer, and an active layer interposed between the first semiconductor layer and the second semiconductor layer, and a reflective electrode layer covering a side surface of the second semiconductor layer which is not covered by an insulating layer. The reflective electrode layer may electrically contact the cathode electrode, and thus an electrical connection path between the cathode electrode and the second semiconductor layer may be additionally provided through the reflective electrode layer. Therefore, display quality of the display device may be improved.

A display device according to embodiments of the disclosure may include a light emitting stack including an anode electrode, a cathode electrode, and a light emitting element which includes a first semiconductor layer, a second semiconductor layer disposed on the first semiconductor layer, and an active layer interposed between the first semiconductor layer and the second semiconductor layer, a first bonding electrode electrically connected to each of the first semiconductor layer and the anode electrode, and a second bonding electrode extending from an upper portion of an insulating layer covering a lower surface of the first semiconductor layer, contacting a side surface of the second semiconductor layer which is not covered by the insulating layer, and electrically connected to the cathode electrode. As described above, as the second bonding electrode electrically contacts the side surface of the second semiconductor layer, the area of the active layer that provides a recombination area (that is, an emission area) of an electron and a hole may be secured as much as possible. Therefore, display quality of the display device may be improved.

### BRIEF DESCRIPTION OF THE DRAWINGS

The above and other features of the disclosure will become more apparent by describing in further detail embodiments thereof with reference to the accompanying drawings, in which:

FIG. 1 is a schematic block diagram illustrating a display device according to embodiments of the disclosure;

FIG. 2 is a schematic block diagram illustrating one sub-pixel among sub-pixels included in the display device of FIG. 1;

FIG. 3 is a schematic plan view illustrating a display panel configuring the display device of FIG. 1;

FIG. 4 is a schematic cross-sectional view illustrating an embodiment of the display panel of FIG. 3;

FIG. 5 is a schematic cross-sectional view illustrating another embodiment of the display panel of FIG. 3;

FIG. 6 is a schematic plan view illustrating an embodiment of a pixel among the pixels included in the display panel of FIG. 3;

FIGS. 7 and 8 are schematic cross-sectional views illustrating the pixel of FIG. 6;

FIGS. 9 to 19 are schematic diagrams illustrating a method of manufacturing a light emitting element included in the pixel of FIG. 7;

FIGS. 20 to 23 are schematic diagrams illustrating a method of manufacturing a light emitting element included in the pixel of FIG. 8;

FIG. 24 is a schematic plan view illustrating another embodiment of a pixel among the pixels included in the display panel of FIG. 3;

FIGS. 25 to 27 are schematic cross-sectional views illustrating the pixel of FIG. 24;

FIGS. 28 to 40 are schematic diagrams illustrating a method of manufacturing a light emitting element included in the pixel of FIG. 25;

FIG. 41 is a schematic block diagram illustrating a display system according to an embodiment; and

FIGS. 42 to 45 are schematic views illustrating application examples of the display system of FIG. 41.

### DETAILED DESCRIPTION OF THE EMBODIMENT

Hereinafter, an embodiment according to the disclosure is described in detail with reference to the accompanying drawings. It should be noted that in the following description, only portions necessary for understanding an operation according to the disclosure are described, and descriptions of other portions are omitted in order not to obscure the subject matter of the disclosure. In addition, the disclosure may be embodied in other forms without being limited to the embodiment described herein. However, the embodiment described herein is provided to describe in detail enough to easily implement the technical spirit of the disclosure to those skilled in the art to which the disclosure belongs.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Terms used herein are for describing specific embodiments and are not intended to limit the disclosure. Throughout the specification, in a case where a certain portion “includes”, the case means that the portion may further include another component without excluding another component unless otherwise stated. “At least any one of X, Y, and Z” and “at least any one selected from an array consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. In addition, the device may face in other directions (for example, rotated 90 degrees or in other directions) and thus the spatially relative terms used herein are interpreted according thereto.

Various embodiments are described with reference to drawings schematically illustrating some embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

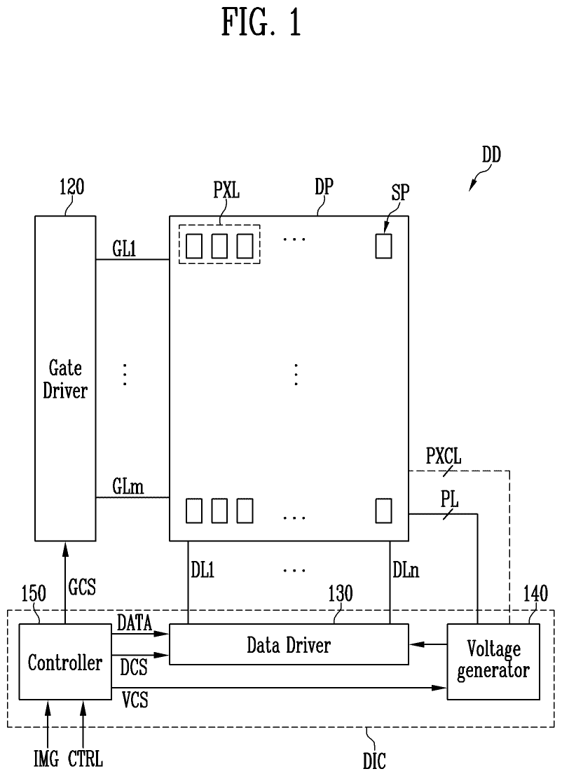

FIG. 1 is a schematic block diagram illustrating a display device according to embodiments of the disclosure.

Referring to FIG. 1, the display device DD may include a display panel DP, a gate driver 120, a data driver 130, a voltage generator 140, and/or a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light of two or more colors. For example, each of the sub-pixels SP may generate light such as red, green, blue, cyan, magenta, or yellow.

Two or more sub-pixels among the sub-pixels SP may configure a pixel PXL. For example, the pixel PXL may include three sub-pixels as shown in FIG. 1. The pixel PXL may emit light of various colors and various luminances according to a combination of light emitted from the sub-pixels included in the pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal, and the like.

The gate driver 120 may be disposed on one side of the display panel DP. However, embodiments are not limited thereto. For example, the gate driver 120 may be divided into two or more physically and/or logically divided drivers, and such drivers may be disposed on one side of the display panel DP and another side of the display panel DP opposite the side. As described above, the gate driver 120 may be disposed around the display panel DP in various shapes according to embodiments.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start signal, a source shift clock, a source output enable signal, and the like.

The data driver 130 may receive voltages from the voltage generator 140. The data driver 130 may apply data signals having grayscale voltages corresponding to the image data DATA to the first to n-th data lines DL1 to DLn using the received voltages. In case that the gate signal is applied to each of the first to m-th gate lines GL1 to GLm, the data signals corresponding to the image data DATA may be applied to the data lines DL1 to DLn. Accordingly, the sub-pixels SP may generate light corresponding to the data signals, and the display panel DP may display an image.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate voltages and provide the generated voltages to components of the display device DD, such as the gate driver 120, the data driver 130, and the controller 150. The voltage generator 140 may generate the voltages by receiving an input voltage from an outside of the display device DD and regulating the received voltage.

The voltage generator 140 may generate a first power voltage and a second power voltage. The generated first and second power voltages may be provided to the sub-pixels SP through power lines PL. In another embodiment, at least one of the first and second power voltages may be provided from the outside of the display device DD.

The voltage generator 140 may provide various voltages and/or signals. For example, the voltage generator 140 may provide one or more initialization voltages applied to the sub-pixels SP. For example, during a sensing operation for sensing electrical characteristics of transistors and/or light emitting elements of the sub-pixels SP, a reference voltage (e.g., a predetermined or selectable reference voltage) may be applied to the first to n-th data lines DL1 to DLn, and the voltage generator 140 may generate the reference voltage and transmit the reference voltage to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide the pixel control signals to the sub-pixels SP through pixel control lines PXCL. In FIG. 1, the pixel control lines PXCL may be connected between the voltage generator 140 and the display panel DP, but embodiments are not limited thereto. For example, the pixel control lines PXCL may be connected between the gate driver 120 and the display panel DP. In this case, the pixel control signals may be transmitted from the voltage generator 140 to the pixel control lines PXCL through the gate driver 120.

The controller 150 may control overall operations of the display device DD. The controller 150 may receive input image data IMG and a control signal CTRL corresponding thereto from the outside. The controller 150 may provide the gate control signal GCS, the data control signal DCS, and/or the voltage control signal VCS in response to the control signal CTRL.

The controller 150 may convert the input image data IMG so that the input image data IMG is suitable for the display device DD or the display panel DP, and may output the image data DATA. In embodiments, the controller 150 may output the image data DATA by aligning the input image data IMG so that the input image data IMG is suitable for the sub-pixels SP of a row unit.

In an embodiment, two or more components of the data driver 130, the voltage generator 140, and the controller 150 may be mounted on an integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in a driver integrated circuit DIC. In other embodiments, at least one of the data driver 130, the voltage generator 140, and the controller 150 may be provided as a component distinguished from the driver integrated circuit DIC.

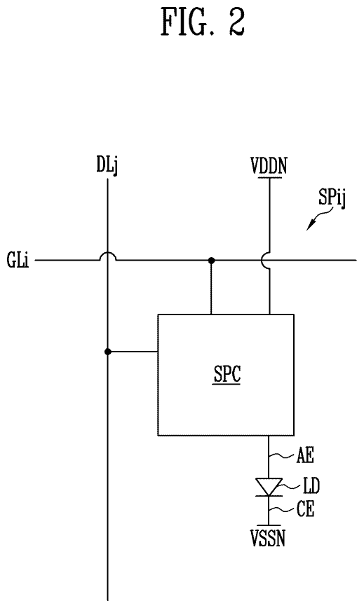

FIG. 2 is a schematic block diagram illustrating a sub-pixel among the sub-pixels included in the display device of FIG. 1. In FIG. 2, among the sub-pixels SP of FIG. 1, a sub-pixel SPij arranged in an i-th row (where i is an integer greater than or equal to 1 and less than or equal to m) and a j-th column (where j is an integer greater than or equal to 1 and less than or equal to n) is shown as an example.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL of FIG. 1 and may receive the first power voltage. The second power voltage node VSSN may be connected to another one of the power lines PL of FIG. 1 and may receive the second power voltage. The first power voltage may have a level higher than that of the second power voltage.

The light emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD may be configured to emit light according to a current flowing from the anode electrode AE to the cathode electrode CE.

The sub-pixel circuit SPC may be connected to an i-th gate line GLi among the first to m-th gate lines GL1 to GLm of FIG. 1, and a j-th data line DLj among the first to n-th data lines DL1 to DLn of FIG. 1. In response to a gate signal received through the i-th gate line GLi, the sub-pixel circuit SPC may control the light emitting element LD to emit light according to a data signal received through the j-th data line DLj. In embodiments, the sub-pixel circuit SPC may be further connected to the pixel control lines PXCL of FIG. 1. In this case, the sub-pixel circuit SPC may control the light emitting element LD in further response to the pixel control signals received through the pixel control lines PXCL.

For such operations, the sub-pixel circuit SPC may include circuit elements, for example, transistors and one or more capacitors.

The transistors of the sub-pixel circuit SPC may include P-type transistors and/or N-type transistors. In embodiments, the transistors of the sub-pixel circuit SPC may include a metal oxide semiconductor field effect transistor (MOSFET). In embodiments, the transistors of the sub-pixel circuit SPC may include an amorphous silicon semiconductor, a monocrystalline silicon semiconductor, a polycrystalline silicon semiconductor, an oxide semiconductor, and the like.

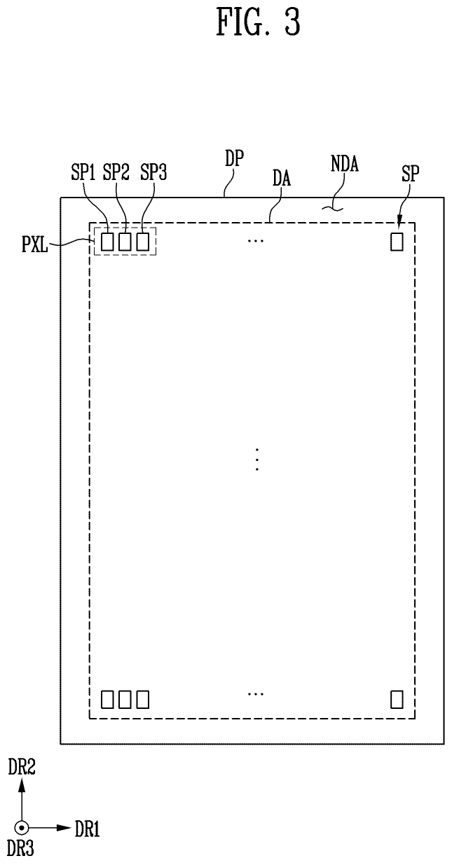

FIG. 3 is a schematic plan view illustrating the display panel configuring the display device of FIG. 1.

Referring to FIG. 3, the display panel DP may include a display area DA and a non-display area NDA. The display panel DP may display an image through the display area DA. The non-display area NDA may be disposed around the display area DA.

The display panel DP may include the sub-pixels SP disposed in the display area DA. The sub-pixels SP may be arranged in a first direction DR1 and a second direction DR2 intersecting the first direction DR1. For example, the sub-pixels SP may be arranged in a matrix form in the first direction DR1 and the second direction DR2. As another example, the sub-pixels SP may be arranged in a zigzag form in the first direction DR1 and the second direction DR2. An arrangement of the sub-pixels SP may vary according to embodiments. The first direction DR1 may be a column direction, and the second direction DR2 may be a row direction.

Two or more sub-pixels among the sub-pixels SP may configure a pixel PXL. In FIG. 3, the pixel PXL may include three sub-pixels SP1, SP2, and SP3, but embodiments are not limited thereto. For example, the pixel PXL may include two sub-pixels. Hereinafter, for convenience of description, it is assumed that the pixel PXL includes the first to third sub-pixels SP1, SP2, and SP3.

Each of the first to third sub-pixels SP1, SP2, and SP3 may generate light of one of various colors such as red, green, blue, cyan, magenta, and yellow. Hereinafter, for clear and concise description, it is assumed that the first sub-pixel SP1 is configured to generate light of a red color, the second sub-pixel SP2 is configured to generate light of a green color, and the third sub-pixel SP3 is configured to generate light of a blue color.

Each of the first to third sub-pixels SP1, SP2, and SP3 may include at least one light emitting element configured to generate light. In embodiments, the light emitting elements of the first to third sub-pixels SP1, SP2, and SP3 may generate light of the same color. For example, the light emitting elements of the first to third sub-pixels SP1, SP2, and SP3 may generate the light of the blue color. In other embodiments, the light emitting elements of the first to third sub-pixels SP1, SP2, and SP3 may generate light of different colors. For example, the light emitting elements of the first to third sub-pixels SP1, SP2, and SP3 may generate light of a red color, a green color, and a blue color, respectively.

As the display panel DP, a light emitting diode display panel (LED display panel) using a micro scale or nano scale of light emitting diode as a light emitting element, and a display panel capable of self-emission such as an organic light emitting display panel (OLED panel) using an organic light emitting diode as a light emitting element may be used.

A component for controlling the sub-pixels SP may be disposed in the non-display area NDA. Lines connected to the sub-pixels SP, for example, the first to m-th gate lines GL1 to GLm of FIG. 1, the first to n-th data lines DL1 to DLn, the power lines PL, and/or the pixel control lines PXCL may be disposed in the non-display area NDA.

At least one of the gate driver 120, the data driver 130, the voltage generator 140, and the controller 150 of FIG. 1 may be disposed in the non-display area NDA of the display panel DP. In embodiments, the gate driver 120 may be disposed in the non-display area NDA. In this case, the data driver 130, the voltage generator 140, and the controller 150 may be implemented as a driver integrated circuit DIC of FIG. 1, separate from the display panel DP, and the driver integrated circuit DIC may be connected to the lines disposed in the non-display area NDA. In other embodiments, the gate driver 120 may be implemented as an integrated circuit separate from the display panel DP, together with the data driver 130, the voltage generator 140, and the controller 150.

In embodiments, the display area DA may have various shapes. The display area DA may have a closed loop shape including sides of a straight line and/or a curved line. For example, the display area DA may have shapes of a polygon, a circle, a semicircle, an ellipse, and the like.

In embodiments, the display panel DP may have a flat display surface. In other embodiments, the display panel DP may have a display surface that is at least partially round. In embodiments, the display panel DP may be bendable, foldable, or rollable. In such cases, the display panel DP and/or a substrate of the display panel DP may include materials having a flexible property.

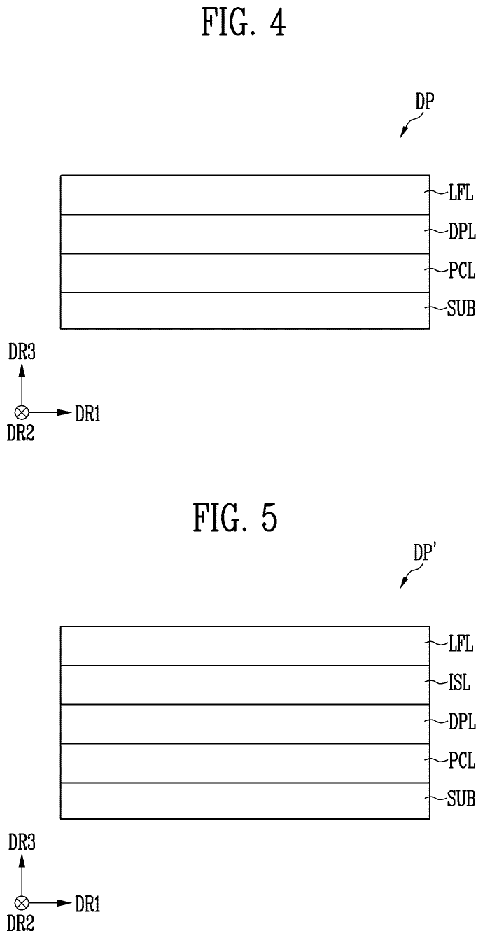

FIG. 4 is a schematic cross-sectional view illustrating an embodiment of the display panel of FIG. 3.

Referring to FIG. 4, the display panel DP may include a substrate SUB, a pixel circuit layer PCL, a display element layer DPL, and a light functional layer LFL sequentially stacked on the substrate SUB in a third direction DR3 intersecting the first and second directions DR1 and DR2.

The substrate SUB may be formed of an insulating material such as glass or resin. For example, the substrate SUB may include a glass substrate. As another example, the substrate SUB may include a polyimide (PI) substrate. As still another example, the substrate SUB may include a silicon wafer substrate formed using a semiconductor process.

In embodiments, the substrate SUB may be formed of a flexible material that may be bent or folded, and may have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers and semiconductor patterns and conductive patterns disposed between the insulating layers. The conductive patterns of the pixel circuit layer PCL may function as circuit elements, lines, and the like.

The circuit elements of the pixel circuit layer PCL may configure the sub-pixel circuit SPC of each of the sub-pixels SP of FIG. 3. In other words, the circuit elements of the pixel circuit layer PCL may be provided as transistors and one or more capacitors of the sub-pixel circuit SPC.

The lines of the pixel circuit layer PCL may include lines connected to the sub-pixels SP. The lines of the pixel circuit layer PCL may include various signal lines and/or voltage lines necessary to drive the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or scattering particles. For example, the color conversion particles may include quantum dots. The quantum dots may change a wavelength (or color) of light emitted from the display element layer DPL. The light functional layer LFL may further include light scattering patterns having the scattering particles. In embodiments, the light conversion patterns and the light scattering patterns may be omitted.

The light functional layer LFL may further include a color filter layer including color filters. The color filter may selectively transmit light of a specific wavelength (or a specific color). In embodiments, the color filter layer may be omitted.

A window for protecting an exposure surface (or an upper surface) of the display panel DP may be provided on the light functional layer LFL. The window may protect the display panel DP from external shock. The window may be coupled (or connected) to the light functional layer LFL through an optically transparent adhesive (or cohesive) member. The window may have a multi-layer structure selected from a glass substrate, a plastic film, and a plastic substrate. The multi-layer structure may be formed through a continuous process or an adhesion process using an adhesive layer. All or a portion of the window may be flexible.

FIG. 5 is a schematic cross-sectional view illustrating another embodiment of the display panel of FIG. 3.

Referring to FIG. 5, a display panel DP′ may include the substrate SUB, the pixel circuit layer PCL, the display element layer DPL, an input sensing layer ISL, and/or the light functional layer LFL. The substrate SUB, the pixel circuit layer PCL, the display element layer DPL, and the light functional layer LFL may be configured equally (or similarly) to the substrate SUB, the pixel circuit layer PCL, the display element layer DPL, and the light functional layer LFL described with reference to FIG. 4. Therefore, a description of an overlapping content is omitted.

The input sensing layer ISL may sense a user's input on an upper surface (or a display surface) of the display panel DP′. The input sensing layer ISL may include components suitable for sensing an external object such as a user's hand or a pen. For example, the input sensing layer ISL may include touch electrodes.

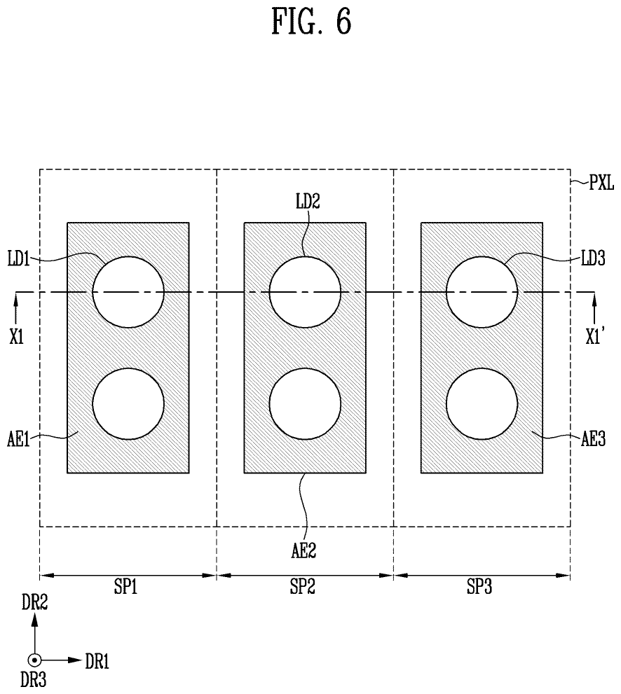

FIG. 6 is a schematic plan view illustrating an embodiment of a pixel among the pixels included in the display panel of FIG. 3.

Referring to FIG. 6, the pixel PXL may include the first to third sub-pixels SP1, SP2, and SP3. The first to third sub-pixels SP1, SP2, and SP3 may be arranged in the first direction DR1. However, an arrangement of the pixel PXL is not limited thereto and may variously change according to embodiments. For example, the first to third sub-pixels SP1, SP2, and SP3 may be arranged in a zigzag.

First to third anode electrodes AE1, AE2, and AE3 may be disposed in the first to third sub-pixels SP1, SP2, and SP3, respectively. The first anode electrode AE1 may be provided as the anode electrode AE (see FIG. 2) included in the sub-pixel circuit SPC (see FIG. 2) of the first sub-pixel SP1. The second anode electrode AE2 may be provided as the anode electrode AE included in the sub-pixel circuit SPC of the second sub-pixel SP2. The third anode electrode AE3 may be provided as the anode electrode AE included in the sub-pixel circuit SPC of the third sub-pixel SP3.

One or more first light emitting elements LD1, one or more second light emitting elements LD2, and one or more third light emitting elements LD3 may be disposed on the first to third anode electrodes AE1, AE2, and AE3, respectively. The first light emitting elements LD1 may be connected to the first anode electrode AE1. The second light emitting elements LD2 may be connected to the second anode electrode AE2. The third light emitting elements LD3 may be connected to the third anode electrode AE3. When light emitting elements are provided in each sub-pixel, each anode electrode may have a shape extending in a specific direction such as the second direction DR2, and light emitting elements connected thereto may be arranged in the same direction.

The first light emitting elements LD1 may be provided as the light emitting element LD (see FIG. 2) included in the first sub-pixel SP1. The second light emitting elements LD2 may be provided as the light emitting element LD included in the second sub-pixel SP2. The third light emitting elements LD3 may be provided as the light emitting element LD included in the third sub-pixel SP3. In case that light emitting elements are provided in a sub-pixel, the light emitting elements may be connected in parallel between the anode electrode and the cathode electrode and may be provided as the light emitting element LD of FIG. 2.

The first light emitting elements LD1, the second light emitting elements LD2, and the third light emitting elements LD3 may be inorganic light emitting diodes including an inorganic light emitting material. However, embodiments are not limited thereto, and for example, organic light emitting diodes or the like may be used.

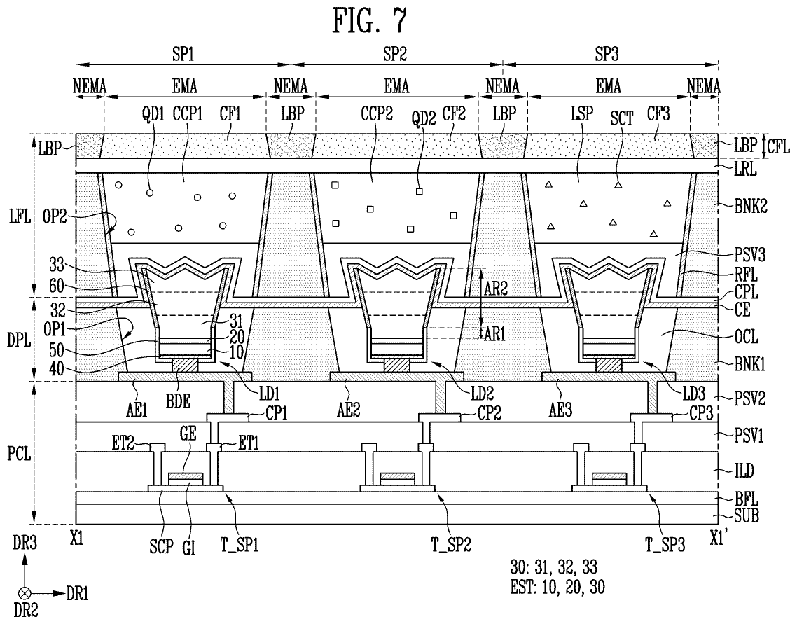

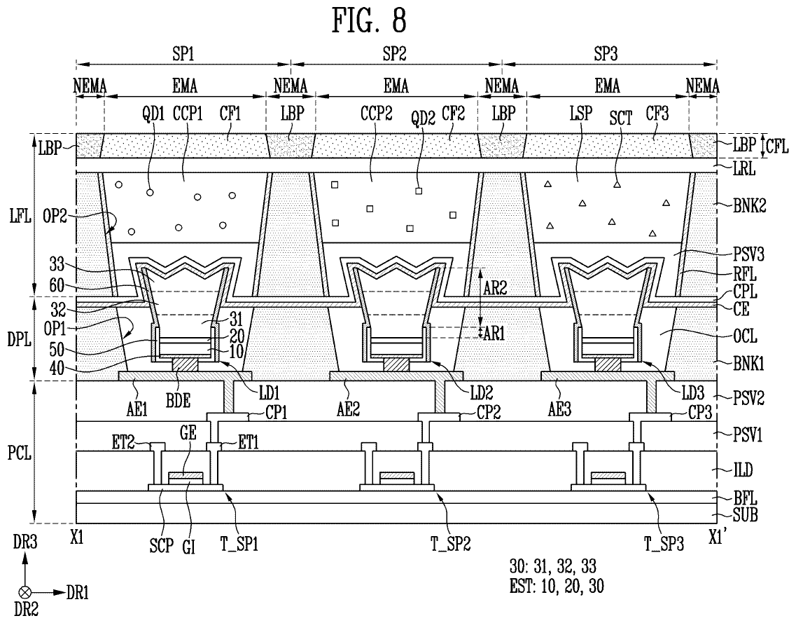

FIGS. 7 and 8 are schematic cross-sectional views illustrating the pixel of FIG. 6. FIGS. 7 and 8 are schematic cross-sectional views taken along line X1-X1′ of FIG. 6.

Referring to FIGS. 6 and 7, the pixel circuit layer PCL, the display element layer DPL, and the light functional layer LFL may be sequentially disposed on the substrate SUB.

The pixel circuit layer PCL may include insulating layers, semiconductor patterns, and conductive patterns stacked on the substrate SUB. The insulating layers may include a buffer layer BFL, one or more interlayer insulating layers ILD, and one or more passivation layers PSV1 and PSV2. The semiconductor patterns and the conductive patterns may be positioned between the insulating layers. For example, the conductive patterns may include at least one material among copper (Cu), molybdenum (Mo), tungsten (W), aluminum neodymium (AlNd), titanium (Ti), aluminum (Al), and silver (Ag).

As described with reference to FIG. 2, the sub-pixel circuit SPC (see FIG. 2) of each of the first to third sub-pixels SP1, SP2, and SP3 may include transistors and one or more capacitors. The semiconductor patterns and the conductive patterns of the pixel circuit layer PCL may function as the transistors and the capacitors of the sub-pixel circuit SPC. The conductive patterns of the pixel circuit layer PCL may further function as lines, for example, the first to m-th gate lines GL1 to GLm, the first to n-th data lines DL1 to DLn, the power lines PL, and the pixel control lines PXCL of FIG. 1.

The buffer layer BFL may be disposed on a surface of the substrate SUB. The buffer layer BFL may prevent an impurity from diffusing into the circuit elements and the lines included in the pixel circuit layer PCL. The buffer layer BFL may include an inorganic insulating layer including an inorganic material. In embodiments, the buffer layer BFL may include at least one of metal oxides such as silicon nitride, silicon oxide, silicon oxynitride, and aluminum oxide. The buffer layer BFL may be provided as a single layer or multiple layers. In case that the buffer layer BFL is provided as the multiple layers, each layer may be formed of the same material or may be formed of different materials.

In embodiments, one or more barrier layers may be disposed between the substrate SUB and the buffer layer BFL. Each of the barrier layers may include polyimide.

First to third transistors T_SP1, T_SP2, and T_SP3 respectively corresponding to the first to third sub-pixels SP1, SP2, and SP3 may be disposed on the buffer layer BFL. The first transistor T_SP1 may be one of the transistors of the sub-pixel circuit SPC included in the first sub-pixel SP1. The second transistor T_SP2 may be one of the transistors of the sub-pixel circuit SPC included in the second sub-pixel SP2. The third transistor T_SP3 may be one of the transistors of the sub-pixel circuit SPC included in the third sub-pixel SP3. Each of the first to third transistors T_SP1, T_SP2, and T_SP3 may be understood as a transistor connected to the anode electrode among the transistors of the corresponding sub-pixel.

The first transistor T_SP1 may include a semiconductor pattern SCP, a gate electrode GE, a first terminal ET1, and/or a second terminal ET2. The first terminal ET1 may be one of a source electrode and a drain electrode, and the second terminal ET2 may be the other one of the source electrode and the drain electrode. For example, the first terminal ET1 may be the source electrode, and the second terminal ET2 may be the drain electrode.

The semiconductor pattern SCP may be disposed on the buffer layer BFL. The semiconductor pattern SCP may include a first contact area contacting the first terminal ET1 and a second contact area contacting the second terminal ET2. An area between the first contact area and the second contact area may be a channel area. The channel area may overlap the gate electrode GE of the first transistor T_SP1. The channel area may be a semiconductor pattern that is not substantially doped with an impurity and may be an intrinsic semiconductor. The first contact area and the second contact area may be a semiconductor pattern doped with an impurity. As the impurity, for example, a p-type impurity may be used, but embodiments are not limited thereto.

The semiconductor pattern SCP may include at least one of various types of semiconductors, for example, an amorphous silicon semiconductor, a monocrystalline silicon semiconductor, a polycrystalline silicon semiconductor, a low-temperature poly silicon semiconductor, and an oxide semiconductor.

The interlayer insulating layers ILD sequentially stacked may be disposed on the semiconductor pattern SCP. The interlayer insulating layers ILD may be inorganic insulating layers including an inorganic material. For example, each of the interlayer insulating layers ILD may include at least one of metal oxides such as silicon nitride, silicon oxide, silicon oxynitride, and aluminum oxide. However, the interlayer insulating layers ILD are not limited thereto. For example, one of the interlayer insulating layers ILD may include an organic insulating layer including an organic material.

The interlayer insulating layers ILD may electrically separate conductive patterns and/or semiconductor patterns disposed between the interlayer insulating layers ILD from each other. For example, the interlayer insulating layers ILD may include a gate insulating layer GI disposed on the semiconductor pattern SCP. The gate insulating layer GI may be disposed between the semiconductor pattern SCP and the gate electrode GE so that the semiconductor pattern SCP is spaced apart from the gate electrode GE. In embodiments, the gate insulating layer GI may be provided entirely on the semiconductor pattern SCP and the buffer layer BFL to cover the semiconductor pattern SCP and the buffer layer BFL. As the number of layers required for the conductive patterns and/or the semiconductor patterns increases, the number of interlayer insulating layers ILD may increase.

The gate electrode GE may be disposed on the gate insulating layer GI. The gate electrode GE may overlap the channel area of the semiconductor pattern SCP. In embodiments, the gate electrode GE may be provided as a single layer including at least one material among copper (Cu), molybdenum (Mo), tungsten (W), aluminum neodymium (AlNd), titanium (Ti), aluminum (Al), and silver (Ag). In embodiments, the gate electrode GE may be provided as multiple layers including at least one material among molybdenum (Mo), titanium (Ti), copper (Cu), aluminum (Al), and silver (Ag), which are low-resistance materials.

The first and second terminals ET1 and ET2 may be disposed on the interlayer insulating layers ILD. The first and second terminals ET1 and ET2 may contact the semiconductor pattern SCP through contact holes passing through the interlayer insulating layers ILD. The first and second terminals ET1 and ET2 may respectively contact the first and second contact areas of the semiconductor pattern SCP. Each of the first and second terminals ET1 and ET2 may include at least one material among copper (Cu), molybdenum (Mo), tungsten (W), aluminum neodymium (AlNd), titanium (Ti), aluminum (Al), and silver (Ag).

Although the first and second terminals ET1 and ET2 are shown as separate electrodes electrically connected to the semiconductor pattern SCP, embodiments are not limited thereto. In embodiments, the first terminal ET1 may be a first contact area adjacent to a side of the channel area of the semiconductor pattern SCP, and the second terminal ET2 may be a second contact area adjacent to another side of the channel area. In this case, the first terminal ET1 may be electrically connected to the light emitting element LD through a connection means such as a bridge electrode disposed on at least one of the interlayer insulating layers ILD.

In embodiments, the first transistor T_SP1 may be configured of a low-temperature polysilicon transistor. However, embodiments are not limited thereto. For example, the first transistor T_SP1 may be configured of an oxide semiconductor transistor. In embodiments, the sub-pixel circuit of each sub-pixel may include different types of transistors. For example, the first transistor T_SP1 may be configured of a low-temperature polysilicon transistor, and another transistor included in the sub-pixel circuit SPC of the first sub-pixel SP1 may be configured of an oxide semiconductor transistor. In this case, the oxide semiconductor of the corresponding oxide semiconductor transistor may be disposed on one of the interlayer insulating layers ILD rather than the insulating layer on which the semiconductor pattern SCP of the first transistor T_SP1 is disposed.

In embodiments, a case where the first transistor T_SP1 is a transistor of a top gate structure is described as an example, but embodiments are not limited thereto. For example, the first transistor T_SP1 may be a transistor of a bottom gate structure. A structure of the first transistor T_SP1 may be variously changed.

Each of the second and third transistors T_SP2 and T_SP3 may be configured similarly to the first transistor T_SP1. Therefore, a description of an overlapping content is omitted.

At least some of the various lines of the display panel DP and/or the display device DD may be further disposed on the interlayer insulating layers ILD.

The first passivation layer PSV1 may be disposed on the interlayer insulating layers ILD and the first and second terminals ET1 and ET2. A passivation layer may be referred to as a protective layer or a via layer. The first passivation layer PSV1 may protect components disposed under the first passivation layer PSV1 and may provide a flat upper surface.

First to third connection patterns CP1, CP2, and CP3 may be disposed on the first passivation layer PSV1. The first to third connection patterns CP1, CP2, and CP3 may be respectively connected to the first terminals ET1 of the first to third transistors T_SP1, T_SP2, and T_SP3 by passing through the first passivation layer PSV1. For example, the first to third connection patterns CP1, CP2, and CP3 may include at least one material among copper (Cu), molybdenum (Mo), tungsten (W), aluminum neodymium (AlNd), titanium (Ti), aluminum (Al), and silver (Ag).

At least some of the various lines of the display panel DP and/or the display device DD may be further disposed on the first passivation layer PSV1.

The second passivation layer PSV2 may be disposed on the first to third connection patterns CP1, CP2, and CP3 and the first passivation layer PSV1. The second passivation layer PSV2 may protect components disposed under the second passivation layer PSV2 and may provide a flat upper surface.

Each of the first and second passivation layers PSV1 and PSV2 may include an inorganic insulating layer including an inorganic material and/or an organic insulating layer including an organic material. The inorganic insulating layer may include, for example, at least one of metal oxides such as silicon oxide, silicon nitride, silicon oxynitride, and aluminum oxide. The organic insulating layer may include, for example, at least one of acrylic resin, epoxy resin, phenol resin, polyamide resin, polyimide resin, unsaturated polyester resin, poly-phenylene ether resin, poly-phenylene sulfide resin, and benzocyclobutene resin.

The first and second passivation layers PSV1 and PSV2 and at least one of the interlayer insulating layers ILD may include a same material, but embodiments are not limited thereto. Each of the first and second passivation layers PSV1 and PSV2 may be provided as a single layer, but may be provided as multiple layers.

The display element layer DPL may be disposed on the second passivation layer PSV2. The display element layer DPL may include the first to third anode electrodes AE1, AE2, and AE3, a first bank BNK1, the first to third light emitting elements LD1, LD2, and LD3, an overcoat layer OCL, the cathode electrode CE, and a capping layer CPL.

The first to third anode electrodes AE1, AE2, and AE3 may be disposed in the first to third sub-pixels SP1, SP2, and SP3, respectively, on the pixel circuit layer PCL.

The first anode electrode AE1 may be electrically connected to the first connection pattern CP1 through a contact hole passing through the second passivation layer PSV2. The second anode electrode AE2 may be electrically connected to the second connection pattern CP2 through another contact hole passing through the second passivation layer PSV2. The third anode electrode AE3 may be electrically connected to the third connection pattern CP3 through still another contact hole passing through the second passivation layer PSV2. As described above, the first to third anode electrodes AE1, AE2, and AE3 may be electrically connected to the first to third transistors T_SP1, T_SP2, and T_SP3, respectively.

The first bank BNK1 may be disposed on the first to third anode electrodes AE1, AE2, and AE3. The first bank BNK1 may have first openings OP1 exposing portions of the first to third anode electrodes AE1, AE2, and AE3. The first to third light emitting elements LD1, LD2, and LD3 may be disposed in the first openings OP1 of the first bank BNK1. As described above, the first bank BNK1 may be provided as a pixel defining layer that defines areas where the first to third light emitting elements LD1, LD2, and LD3 are positioned.

The first bank BNK1 may be configured to include a light blocking material to prevent light mixing between adjacent sub-pixels. In embodiments, the first bank BNK1 may include an organic material. For example, the first bank BNK1 may include an organic insulating material such as acryl resin, epoxy resin, phenol resin, polyamide resin, and polyimide resin. According to embodiments, in order to further improve light output efficiency, a reflective layer including a reflective material may be further disposed on a side surface of the first bank BNK1 adjacent to the first openings OP1.

The first to third light emitting elements LD1, LD2, and LD3 may be disposed on the first to third anode electrodes AE1, AE2, and AE3, respectively. The first to third light emitting elements LD1, LD2, and LD3 may be bonded and coupled to the first to third anode electrodes AE1, AE2, and AE3, respectively.

The first light emitting element LD1 may include a bonding electrode BDE, a light emitting stack EST, an insulating layer 50, and a reflective electrode layer 60. The light emitting stack EST may include a first semiconductor layer 10, an active layer 20, and a second semiconductor layer 30. The first light emitting element LD1 may be implemented as a vertical light emitting stack in which the bonding electrode BDE, the first semiconductor layer 10, the active layer 20, and the second semiconductor layer 30 are sequentially stacked in the third direction DR3.

The first semiconductor layer 10 may be configured to provide a hole. The first semiconductor layer 10 may have a first polarity. For example, the first semiconductor layer 10 may include at least one p-type semiconductor layer. For example, the first semiconductor layer 10 may include at least one semiconductor material among gallium nitride (GaN), aluminum gallium nitride (AlGaN), indium gallium nitride (InGaN), aluminum nitride (AlN), and indium nitride (InN), and may be a p-type semiconductor layer doped with a first conductive dopant (or a p-type dopant), such as magnesium (Mg), zinc (Zn), calcium (Ca), strontium (Sr), or barium (Ba). However, a material configuring the first semiconductor layer 10 is not limited thereto, and various other materials may configure the first semiconductor layer 10. In an embodiment of the disclosure, the first semiconductor layer 10 may include a gallium nitride (GaN) semiconductor material doped with the first conductive dopant (or the p-type dopant).

The second semiconductor layer 30 may be disposed on the first semiconductor layer 10 and may be configured to provide an electron. The second semiconductor layer 30 may have a second polarity different from the first polarity. For example, the second semiconductor layer 30 may include at least one n-type semiconductor layer. For example, the second semiconductor layer 30 may include at least one semiconductor material among gallium nitride (GaN), aluminum gallium nitride (AlGaN), indium gallium nitride (InGaN), aluminum nitride (AlN), and indium nitride (InN), and may be an n-type semiconductor layer doped with a second conductive dopant (or an n-type dopant) such as silicon (Si), germanium (Ge), and tin (Sn). However, a material configuring the second semiconductor layer 30 is not limited thereto, and various other materials may configure the second semiconductor layer 30. In an embodiment of the disclosure, the second semiconductor layer 30 may include a gallium nitride (GaN) semiconductor material doped with the second conductive dopant (or the n-type dopant).

In embodiments, the second semiconductor layer 30 may include a first doping area 31, a second doping area 32, and a third doping area 33 sequentially in the third direction DR3. The first doping area 31 may be an area where a dopant is doped at a relatively high concentration, and the third doping area 33 may be an area where a dopant is not doped substantially or a dopant is doped at a relatively low concentration. The second doping area 32 may be an area where a dopant is doped at a concentration lower than that of the first doping area 31 and higher than that of the third doping area 33.

A first average doping concentration of the dopant doped into the second semiconductor layer 30 in the first doping area 31 may be greater than a second average doping concentration of the dopant doped into the second semiconductor layer 30 in the second doping area 32. For example, the first average doping concentration may be about 8 times or more than the second average doping concentration. The second average doping concentration of the dopant doped into the second semiconductor layer 30 in the second doping area 32 may be greater than a third average doping concentration of the dopant doped into the second semiconductor layer 30 in the third doping area 33. For example, the second average doping concentration may be about 8 times or more than the third average doping concentration.

The active layer 20 may be interposed (or disposed) between the first semiconductor layer 10 and the second semiconductor layer 30 and may provide an area where the electron and the hole are recombined. As the electron and the hole recombine in the active layer 20, the electron and the hole may transit to a lower energy level, and thus light having a wavelength corresponding thereto may be generated. The active layer 20 may be formed as a single or multiple quantum wells structure. In case that the active layer 20 is formed as the multiple quantum wells structure, a part including a barrier layer, a strain reinforcing layer, and a well layer may be repeatedly stacked each other to form the active layer 20. However, the active layer 20 is not limited to the above-described structure.

The bonding electrode BDE may be disposed under the first semiconductor layer 10. The bonding electrode BDE may be electrically connected to the first semiconductor layer 10. In embodiments, the bonding electrode BDE of the first light emitting element LD1 may be electrically connected to the first anode electrode AE1. The bonding electrode BDE may include a eutectic metal.

The insulating layer 50 may cover a portion of an outer peripheral surface of the light emitting stack EST. In this case, the insulating layer 50 may cover at least a side surface of the active layer 20. The insulating layer 50 may serve to prevent an electrical short circuit that may occur in case that the active layer 20 contacts a conductive material other than the first and second semiconductor layers 10 and 30. The insulating layer 50 may include a transparent insulating material. The insulating layer 50 may be configured to expose at least a portion of the bonding electrode BDE.

In embodiments, the insulating layer 50 may be configured to entirely cover an outer peripheral surface of the first semiconductor layer 10 and the outer peripheral surface of the active layer 20, and to cover a side surface of the second semiconductor layer 30 in a first area AR1. Here, the first area AR1 may be an area adjacent to the active layer 20 in the second semiconductor layer 30. The first area AR1 may be an area of the first doping area 31 adjacent to the active layer 20.

In this case, the insulating layer 50 may be configured not to cover a second area AR2 of the second semiconductor layer 30. Here, the second area AR2 may be an area above the first area AR1, and may include an area except for an area adjacent to the active layer 20 of the first doping areas 31, and the second and third doping areas 32 and 33.

In embodiments, an auxiliary electrode 40 may be further disposed between the bonding electrode BDE and the first semiconductor layer 10. The auxiliary electrode 40 may be formed of a conductive material having a reflectance (e.g., a predetermined or selectable reflectance). The conductive material may include an opaque metal. The opaque metal may include, for example, a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof. Accordingly, light emitted from the first light emitting element LD1 may be output more efficiently toward the light functional layer LFL. However, a material of the auxiliary electrode 40 is not limited thereto.

The reflective electrode layer 60 may cover a side surface of the second semiconductor layer 30 which is not covered by the insulating layer 50. For example, the reflective electrode layer 60 may entirely cover the side surface of the second semiconductor layer 30 in the second area AR2. In this case, the reflective electrode layer 60 may electrically contact the cathode electrode CE to be described below. Accordingly, the second power voltage applied to the cathode electrode CE may be transmitted to the second semiconductor layer 30 through the reflective electrode layer 60.

The reflective electrode layer 60 may be formed of a conductive material having a reflectance (e.g., a predetermined or selectable reflectance). For example, the reflective electrode layer 60 may include, for example, a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof. Accordingly, the light emitted from the first light emitting element LD1 may be output more efficiently toward the light functional layer LFL. In this case, the reflective electrode layer 60 may include at least one selected from a group consisting of aluminum (Al), titanium (Ti), and chromium (Cr), a work function of which is relatively low. As described above, in case that the reflective electrode layer 60 includes a material, a work function of which is relatively low, a contact resistance between the reflective electrode layer 60 and the second semiconductor layer 30 may become relatively low, and thus efficiency of the first light emitting element LD1 may be further improved.

In embodiments, the reflective electrode layer 60 may not cover an upper surface of the light emitting stack EST. For example, the reflective electrode layer 60 may be configured to expose the upper surface of the second semiconductor layer 30. Accordingly, the light emitted from the first light emitting element LD1 and proceeding toward the light functional layer LFL may not be substantially blocked by the reflective electrode layer 60.

In embodiments, the reflective electrode layer 60 may directly contact at least a portion of the side surface of the second semiconductor layer 30 in the first doping area 31. For example, the second semiconductor layer 30 and the reflective electrode layer 60 may electrically contact each other in the first doping area 31 where the doping concentration is relatively high. Therefore, efficiency of the first light emitting element LD1 may be further improved.

In embodiments, the side surface of the second semiconductor layer 30 which is not covered by the insulating layer 50 may have an inverse taper shape, a width of which gradually increases in the third direction DR3. For example, in the second area AR2, the side surface of the second semiconductor layer 30 may have an inverse taper shape. Accordingly, reflection efficiency of the reflective electrode layer 60 covering the side surface of the second semiconductor layer 30 may be further improved, and thus the light emitted from the first light emitting element LD1 may be output more efficiently toward the light functional layer LFL.

In embodiments, the upper surface of the light emitting stack EST may have a concave-convex shape. For example, an upper surface of the second semiconductor layer 30 may have a concavo-convex shape, and the concavo-convex shape may be implemented in the third doping area 33 of the second semiconductor layer 30. However, embodiments are not limited thereto, and the concavo-convex shape may be implemented in the second and third doping areas 32 and 33 of the second semiconductor layer 30. As described above, as the upper surface of the light emitting stack EST has the concavo-convex shape, light output efficiency of the light emitted from the first light emitting element LD1 may be improved.

Each of the second and third light emitting elements LD2 and LD3 may be configured similarly to the first light emitting element LD1. Therefore, a description of an overlapping content is omitted.

The overcoat layer OCL may be disposed in the first openings OP1 where the first to third light emitting elements LD1, LD2, and LD3 are disposed. The overcoat layer OCL may fix the first to third light emitting elements LD1, LD2, and LD3 bonded to the first to third anode electrodes AE1, AE2, and AE3 so that the first to third light emitting elements LD1, LD2, and LD3 do not move. The overcoat layer OCL may protect configurations or components disposed under the overcoat layer OCL from a foreign substance such as dust and moisture. The overcoat layer OCL may include at least one of an inorganic insulating layer and an organic insulating layer. For example, the overcoat layer OCL may include epoxy, but embodiments are not limited thereto.

In embodiments, the overcoat layer OCL may not be disposed on an upper surface of the first to third light emitting elements LD1, LD2, and LD3. The first to third light emitting elements LD1, LD2, and LD3 may protrude into the light functional layer LFL. The first to third light emitting elements LD1, LD2, and LD3 may be at least partially positioned in second openings OP2 of a second bank BNK2. For example, a height of the upper surface of each of the first to third light emitting elements LD1, LD2, and LD3 from the substrate SUB may be higher than that of the lowest end of a reflective layer RFL. Accordingly, light emitted from the first to third light emitting elements LD1, LD2, and LD3 may be provided to the light functional layer LFL at a relatively high rate.

The cathode electrode CE may be disposed on the first to third light emitting elements LD1, LD2, and LD3. The cathode electrode CE may be entirely disposed on the first bank BNK1, the first to third light emitting elements LD1, LD2, and LD3, and the overcoat layer OCL. The cathode electrode CE may contact an upper surface of the second semiconductor layer 30 of each of the first to third light emitting elements LD1, LD2, and LD3 and a reflective electrode layer 60. The cathode electrode CE may be electrically connected to the second power voltage node VSSN of FIG. 2. The second power voltage applied to the second power voltage node VSSN may be transmitted to the first to third light emitting elements LD1, LD2, and LD3 through the cathode electrode CE.

The cathode electrode CE may be configured to be substantially transparent or translucent to satisfy a light transmittance (e.g., a predetermined or selectable light transmittance). In embodiments, the cathode electrode CE may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, a material of the cathode electrode CE is not limited thereto.

As described above, as the cathode electrode CE includes a material that satisfies a light transmittance (e.g., a predetermined or selectable light transmittance), a contact resistance between the cathode electrode CE and the second semiconductor layer 30 may become relatively high. In this case, assuming that the reflective electrode layer 60 of the first to third light emitting elements LD1, LD2, and LD3 does not exist, driving efficiency of the first to third light emitting elements LD1, LD2, and LD3 may be deteriorated.

In the disclosure, as the first to third light emitting elements LD1, LD2, and LD3 include the reflective electrode layer 60, an electrical connection path between the cathode electrode CE and the second semiconductor layer 30 may be additionally provided through the reflective electrode layer 60. Here, a contact resistance between the reflective electrode layer 60 and the second semiconductor layer 30 may be relatively low. Accordingly, driving efficiency of the first to third light emitting elements LD1, LD2, and LD3 may be improved.

The capping layer CPL may be disposed on the cathode electrode CE. The capping layer CPL may protect components under the capping layer CPL, such as the cathode electrode CE and the first to third light emitting elements LD1, LD2, and LD3 from external water, moisture, and the like. The capping layer CPL may include at least one of metal oxides such as silicon nitride, silicon oxide, silicon oxynitride, and aluminum oxide. However, a material of the capping layer CPL is not limited thereto.

The light functional layer LFL may be disposed on the capping layer CPL. The light functional layer LFL may include the second bank BNK2, the reflective layer RFL, a third passivation layer PSV3, first and second light conversion patterns CCP1 and CCP2, a light scattering pattern LSP, a low refractive layer LRL, and a color filter layer CFL.

The second bank BNK2 may be disposed on the capping layer CPL. The second bank BNK2 may overlap the first bank BNK1. The second bank BNK2 may have the second openings OP2 overlapping the first openings OP1.

The second bank BNK2 may be configured to include a light blocking material, thereby preventing light mixing between adjacent sub-pixels and the first to third sub-pixels SP1, SP2, and SP3. In embodiments, the second bank BNK2 may include an organic material. For example, the second bank BNK2 may include an organic insulating material such as acryl resin, epoxy resin, phenol resin, polyamide resin, and polyimide resin.

The reflective layer RFL may be disposed on side surfaces of the second bank BNK2 adjacent to the second openings OP2. The reflective layer RFL may be configured to reflect incident light, and thus light output efficiency may be improved. The reflective layer RFL may include a material suitable for reflecting light. For example, the reflective layer RFL may include at least one among aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them. However, embodiments are not limited thereto.

It may be understood that an emission area EMA and a non-emission area NEMA for the first to third sub-pixels SP1, SP2, and SP3 are defined by the second bank BNK2. An area overlapping the second bank BNK2 may correspond to the non-emission area NEMA. An area overlapping the second openings OP2 of the second bank BNK2 may correspond to the emission area EMA.

The third passivation layer PSV3 may be disposed in the second openings OP2, on the capping layer CPL. The third passivation layer PSV3 may protect components disposed under the third passivation layer PSV3 and may provide a flat upper surface. The third passivation layer PSV3 and at least one of the first and second passivation layers PSV1 and PSV2 may include the same material, but embodiments are not limited thereto.

The first and second light conversion patterns CCP1 and CCP2 and the light scattering pattern LSP may be disposed in the second openings OP2, on the third passivation layer PSV3.

The first and second light conversion patterns CCP1 and CCP2 and the light scattering pattern LSP may include color conversion particles and/or scattering particles. The color conversion particles may change a wavelength of incident light and convert the incident light into light of another color. The color conversion particles may scatter the incident light. In embodiments, the color conversion particles may be quantum dots. The scattering particles may scatter the incident light.

In embodiments, the first to third light emitting elements LD1, LD2, and LD3 may be configured to emit light of a blue color. In this case, the first light conversion pattern CCP1 may include first color conversion particles QD1 configured to convert the light of the blue color into light of a red color. The second light conversion pattern CCP2 may include second color conversion particles QD2 configured to convert the light of the blue color into light of a green color. The light scattering pattern LSP may include scattering particles SCT that scatter the light of the blue color to improve light output efficiency. Accordingly, the first to third sub-pixels SP1, SP2, and SP3 may be provided as a red sub-pixel, a green sub-pixel, and a blue sub-pixel, respectively. In embodiments, at least one of the first and second light conversion patterns CCP1 and CCP2 and the light scattering pattern LSP may further include color conversion particles that convert the light of the blue color into light of a white color.

In embodiments, the first to third light emitting elements LD1, LD2, and LD3 may be configured to emit the light of the red color, the green color, and the blue color, respectively. In this case, each of the first and second light conversion patterns CCP1 and CCP2 and the light scattering pattern LSP may include scattering particles SCT. As described above, according to a color of light emitted from the first to third light emitting elements LD1, LD2, and LD3, particles included in the first and second light conversion patterns CCP1 and CCP2 and the light scattering pattern LSP may be variously changed.

In embodiments, the first and second light conversion patterns CCP1 and CCP2 and the light scattering pattern LSP may be omitted.

The low refractive layer LRL may be disposed on the second bank BNK2, the reflective layer RFL, the first and second light conversion patterns CCP1 and CCP2, and the light scattering pattern LSP. The low refractive layer LRL may have a refractive index lower than that of the first and second light conversion patterns CCP1 and CCP2 and the light scattering pattern LSP. The low refractive layer LRL may be configured to refract or totally reflect corresponding light according to an incidence angle of light. The low refractive layer LRL may provide light passing through the first and second light conversion patterns CCP1 and CCP2 and the light scattering pattern LSP back to the first and second light conversion patterns CCP1 and CCP2 and the light scattering pattern LSP, and thus light conversion efficiency and light scattering efficiency of the first and second light conversion patterns CCP1 and CCP2 and the light scattering pattern LSP may be improved. In embodiments, the low refractive layer LRL may be omitted in an area corresponding to the third sub-pixel SP3.

The color filter layer CFL may be disposed on the low refractive layer LRL. The color filter layer CFL may include first to third color filters CF1, CF2, and CF3, and light blocking patterns LBP.

The first to third color filters CF1, CF2, and CF3 may overlap the first and second light conversion patterns CCP1 and CCP2 and the light scattering pattern LSP, respectively. Each of the first to third color filters CF1, CF2, and CF3 may selectively transmit light of a desired wavelength range. In case that the first sub-pixel SP1 is a red sub-pixel, the first color filter CF1 may include a red color filter. In case that the second sub-pixel SP2 is a green sub-pixel, the second color filter CF2 may include a green color filter. In case that the third sub-pixel SP3 is a blue sub-pixel, the third color filter CF3 may include a blue color filter. The first to third color filters CF1, CF2, and CF3 may have a refractive index higher than that of the low refractive layer LRL. However, embodiments are not limited thereto, and the first to third color filters CF1, CF2, and CF3 may have a refractive index lower than or equal to that of the low refractive layer LRL.

The light blocking patterns LBP may be disposed between the first to third color filters CF1, CF2, and CF3. It may be understood that the emission area (or a light output area) EMA and the non-emission area NEMA for the first to third sub-pixels SP1, SP2, and SP3 are defined by the light blocking patterns LBP. An area overlapping the light blocking patterns LBP may correspond to the non-emission area NEMA. An area that does not overlap the light blocking patterns LBP may correspond to the emission area EMA.

In embodiments, the light blocking patterns LBP may include at least one of various types of light blocking materials. In embodiments, each of the light blocking patterns LBP may be provided in a form of multiple layers in which at least two color filters among the first to third color filters CF1, CF2, and CF3 overlap each other. For example, each of the light blocking patterns LBP may be formed by overlapping the first to third color filters CF1, CF2, and CF3 each other. As another example, a light blocking pattern between the first and second color filters CF1 and CF2 among the light blocking patterns LBP may be formed as multiple layers in which the first and second color filters CF1 and CF2 overlap each other, and a light blocking pattern between the second and third color filters CF2 and CF3 among the light blocking patterns LBP may be formed as multiple layers in which the second and third color filters CF2 and CF3 overlap each other. A light blocking pattern between the first color filter CF1 and the third color filter CF3 of a neighboring pixel may be formed as multiple layers in which the first and third color filters CF1 and CF3 overlap each other. As described above, each of the first to third color filters CF1, CF2, and CF3 may extend to the non-emission area NEMA to form the light blocking patterns LBP.

Referring to FIGS. 6 and 8, the pixel circuit layer PCL, the display element layer DPL, and the light functional layer LFL may be sequentially disposed on the substrate SUB.

Hereinafter, the disclosure is described based on a difference between the embodiment and the embodiment described with reference to FIGS. 6 and 7, and parts omitted from the description are replaced with the content described above.

The reflective electrode layer 60 may further cover a portion of the insulating layer 50. For example, the reflective electrode layer 60 may further cover the insulating layer 50 covering the side surface of the first semiconductor layer 10, the side surface of the active layer 20, and the side surface of the second semiconductor layer 30 in the first area AR1. Accordingly, the light emitted from the first light emitting element LD1 may be output more efficiently toward the light functional layer LFL.

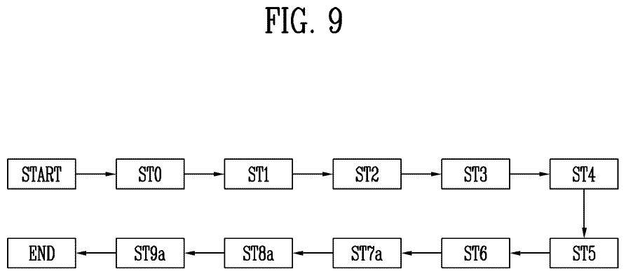

FIGS. 9 to 19 are schematic diagrams illustrating a method of manufacturing a light emitting element included in the pixel of FIG. 7.

Referring to FIG. 9, in order to manufacture a light emitting element LD, a preparation step ST0 and first to ninth steps ST1, ST2, ST3, ST4, ST5, ST6, ST7a, ST8a, and ST9a may be performed.

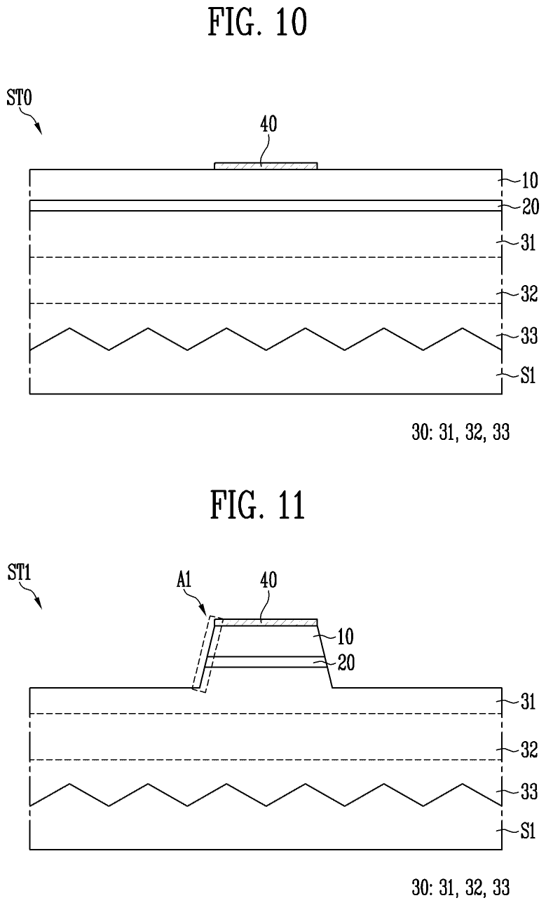

Referring to FIG. 10, after sequentially forming the second semiconductor layer 30, the active layer 20, and the first semiconductor layer 10 on a substrate S1, the auxiliary electrode 40 may be formed on the first semiconductor layer 10 (ST0).

The substrate S1 may be, for example, a sapphire substrate. In embodiments, in the substrate S1, a concave-convex structure corresponding to a shape of an upper surface of the light emitting elements LD1, LD2, and LD3 described with reference to FIG. 7 may be formed.

A method of forming the second semiconductor layer 30, the active layer 20, and the first semiconductor layer 10 on the substrate S1 is not limited. For example, an epitaxial process for sequentially forming the second semiconductor layer 30, the active layer 20, and the first semiconductor layer 10 may be performed.

In this case, the second semiconductor layer 30 may include the first doping area 31, the second doping area 32, and the third doping area 33. The first to third doping areas 31, 32, and 33 may be formed, for example, by varying a doping concentration of a dopant when performing the epitaxial process.

Referring to FIG. 11, the first semiconductor layer 10, the active layer 20, and the second semiconductor layer 30 may be firstly etched using the auxiliary electrode 40 as a mask (ST1).

In embodiments, the first etching may be dry etching. Accordingly, a first surface A1 defined as the first semiconductor layer 10, the active layer 20, and the second semiconductor layer 30 are removed through the first etching may be provided as an inclined surface.

In embodiments, only a portion of the first doping area 31 of the second semiconductor layer 30 may be removed by the first etching.

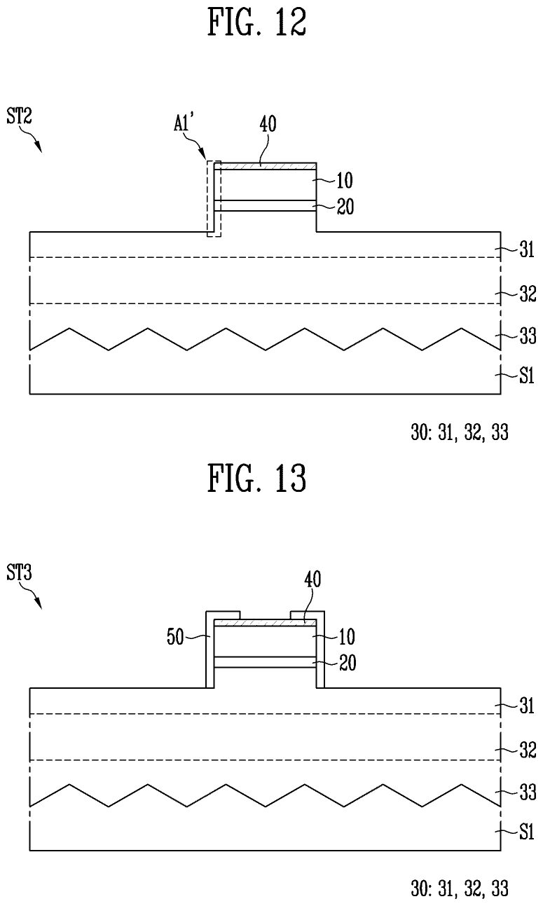

Referring to FIG. 12, the first semiconductor layer 10, the active layer 20, and the second semiconductor layer 30 may be secondly etched using the auxiliary electrode 40 as a mask (ST2).

In embodiments, the second etching may be wet etching. Accordingly, the first semiconductor layer 10, the active layer 20, and the second semiconductor layer 30 may be additionally removed by the second etching, and thus a first surface A1′ in which an inclination of the first surface A1 (see FIG. 11) is removed may be provided.

Referring to FIG. 13, the insulating layer 50 may be formed (ST3). The insulating layer 50 may be appropriately patterned. Accordingly, the insulating layer 50 may entirely cover the first surface A1′ (see FIG. 12) and a portion of the auxiliary electrode 40.

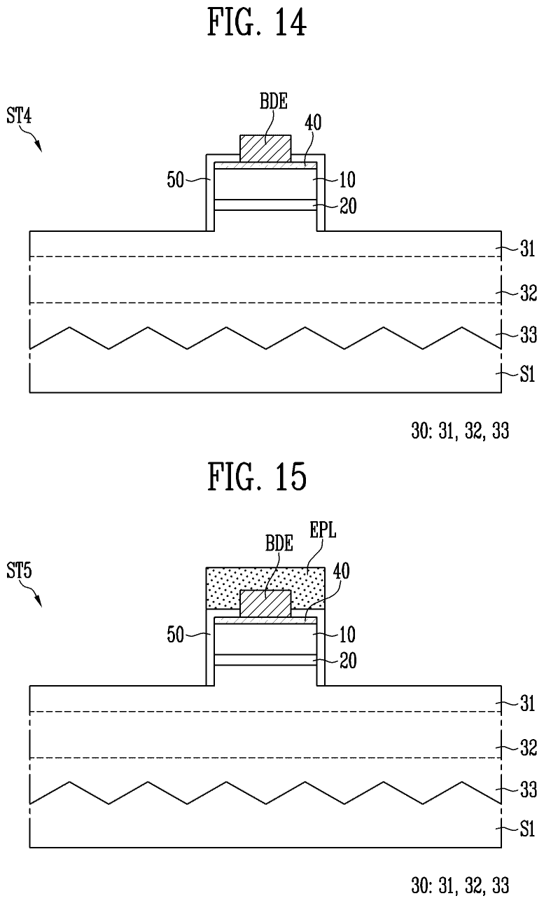

According to embodiments, a step of removing the auxiliary electrode 40 may be further performed after performing the second step ST2 (see FIG. 12). In this case, the insulating layer 50 may be provided to cover a portion of the first semiconductor layer 10. Referring to FIG. 14, the bonding electrode BDE may be formed on the auxiliary electrode 40 that is exposed and not covered by the insulating layer 50 (ST4). The bonding electrode BDE may be electrically connected to the first semiconductor layer 10 through the auxiliary electrode 40.

According to embodiments, when the auxiliary electrode 40 is removed, the bonding electrode BDE may be provided to directly contact the first semiconductor layer 10.

Referring to FIG. 15, an etch protective layer EPL may be formed to cover the bonding electrode BDE and the insulating layer 50 covering the auxiliary electrode 40 (ST5). The etch protective layer EPL may serve to prevent components disposed under the etch protective layer EPL from being etched by thirdly etching to be described below.

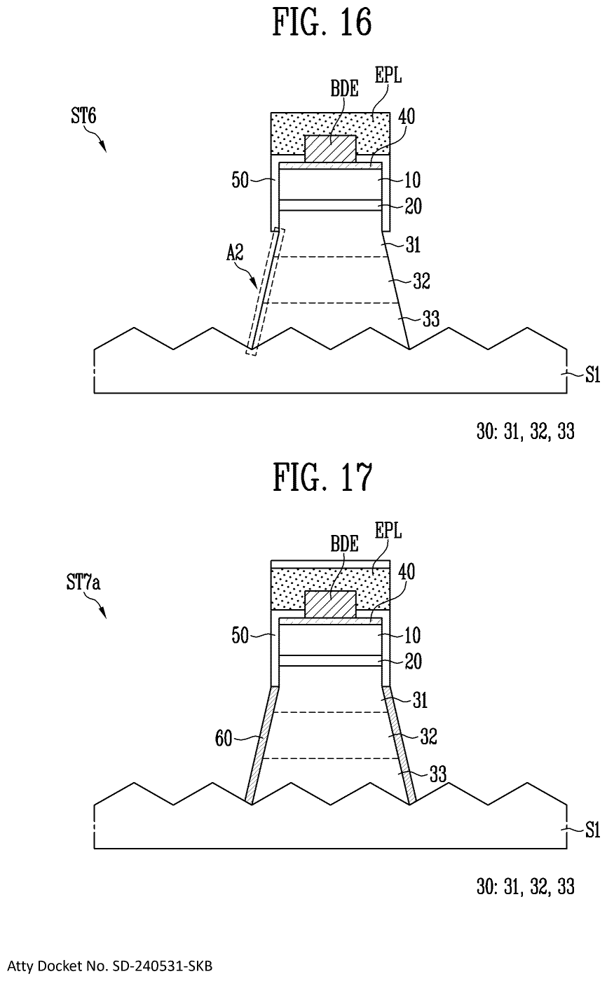

Referring to FIG. 16, the second semiconductor layer 30 may be thirdly etched using the etch protective layer EPL as a mask (ST6).

In embodiments, the third etching may be dry etching. Accordingly, a second surface A2 defined as the second semiconductor layer 30 is removed through the third etching may be provided as an inclined surface.

In embodiments, the first to third doping areas 31, 32, and 33 of the second semiconductor layer 30 may be removed by the third etching, and thus the substrate S1 may be exposed.

Referring to FIG. 17, the reflective electrode layer 60 may be formed by anisotropic deposition (ST7a). As the reflective electrode layer 60 is formed by the anisotropic deposition, the reflective electrode layer 60 may be provided to cover the second surface A2 which is an inclined surface and an upper surface of the etch protective layer EPL and expose a side surface of the etch protective layer EPL and a side surface of the insulating layer 50.

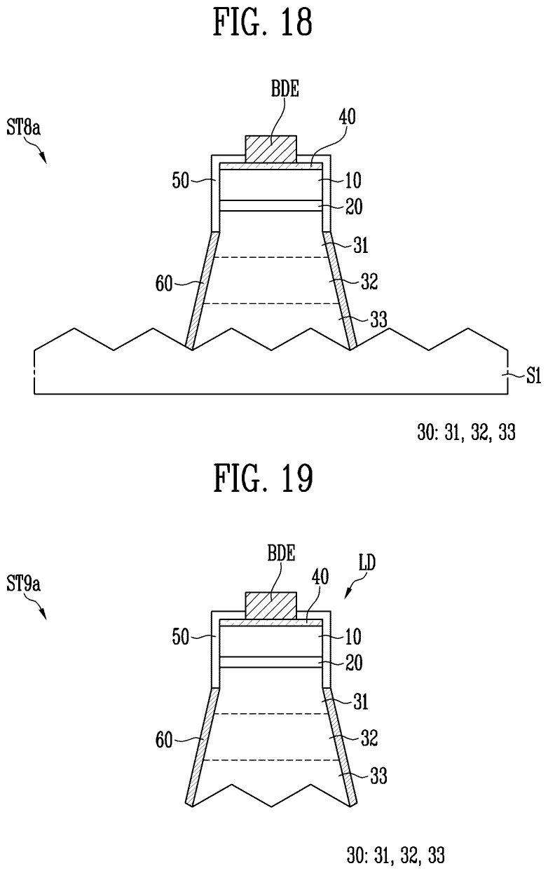

Referring to FIG. 18, the etch protective layer EPL may be removed (ST8a). Accordingly, the reflective electrode layer 60 covering the upper surface of the etch protective layer EPL may be removed.

Referring to FIG. 19, the light emitting element LD may be separated from the substrate S1 (ST9a). For example, a laser or the like may be irradiated to a boundary between the light emitting element LD and the substrate S1. The separated light emitting element LD may be provided on the pixel circuit layer PCL described with reference to FIG. 7 using various known transfer means (or methods).

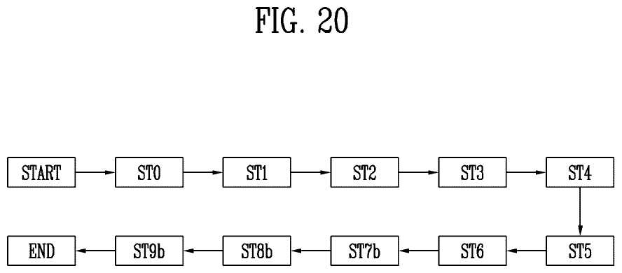

FIGS. 20 to 23 are schematic diagrams illustrating a method of manufacturing a light emitting element included in the pixel of FIG. 8.

Referring to FIG. 20, in order to manufacture the light emitting element LD, a preparation step ST0 and first to ninth steps ST1, ST2, ST3, ST4, ST5, ST6, ST7b, ST8b, and ST9b may be performed.

The preparation step ST0 and the first to sixth steps ST1, ST2, ST3, ST4, ST5, and ST6 may be substantially the same as those described with reference to FIGS. 9 to 16. Therefore, a description of an overlapping content is omitted.

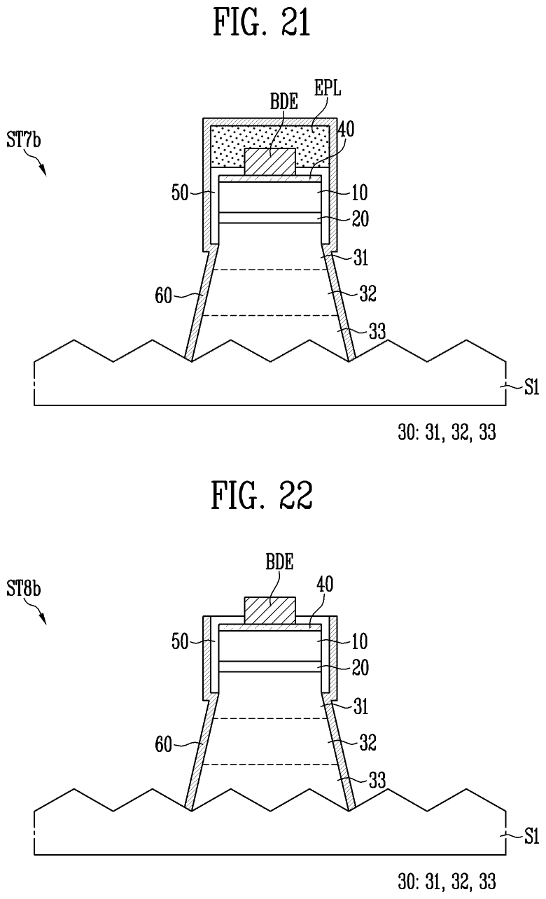

Referring to FIG. 21, the reflective electrode layer 60 may be formed by isotropic deposition (ST7b). As the reflective electrode layer 60 is formed by the isotropic deposition, the reflective electrode layer 60 may be provided to entirely cover the second surface A2 (see FIG. 16), the etch protective layer EPL, and the insulating layer 50.

Referring to FIG. 22, the etch protective layer EPL may be removed (ST8b). Accordingly, the reflective electrode layer 60 covering the etch protective layer EPL may be removed.

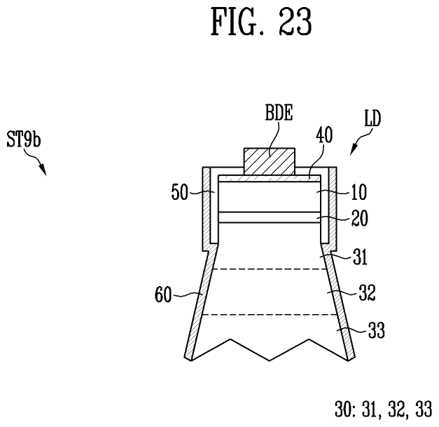

Referring to FIG. 23, the light emitting element LD may be separated from the substrate S1 (ST9b). For example, a laser or the like may be irradiated to the boundary between the light emitting element LD and the substrate S1. The separated light emitting element LD may be provided on the pixel circuit layer PCL described with reference to FIG. 8 using various known transfer means (or methods).

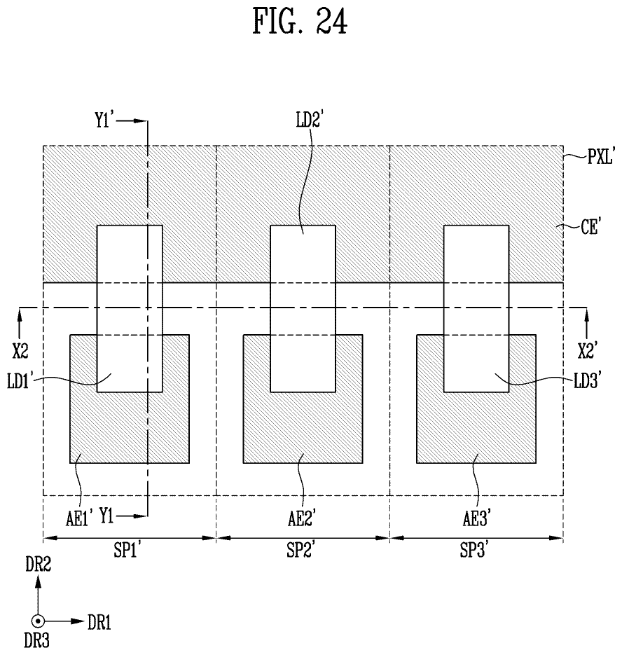

FIG. 24 is a schematic plan view illustrating another embodiment of a pixel among the pixels included in the display panel of FIG. 3.

Referring to FIG. 24, a pixel PXL′ may include first to third sub-pixels SP1′, SP2′, and SP3′. The first to third sub-pixels SP1′, SP2′, and SP3′ may be arranged in the first direction DR1. However, an arrangement of the pixels PXL′ is not limited thereto and may change variously according to embodiments. For example, the first to third sub-pixels SP1′, SP2′, and SP3′ may be arranged in a zigzag pattern.

First to third anode electrodes AE1′, AE2′, and AE3′ may be disposed in the first to third sub-pixels SP1′, SP2′, and SP3′, respectively. The first anode electrode AE1′ may be provided as the anode electrode AE (see FIG. 2) connected to the sub-pixel circuit SPC (see FIG. 2) of the first sub-pixel SP1′. The second anode electrode AE2′ may be provided as the anode electrode AE connected to the sub-pixel circuit SPC of the second sub-pixel SP2′. The third anode electrode AE3′ may be provided as the anode electrode AE connected to the sub-pixel circuit SPC of the third sub-pixel SP3′.

A cathode electrode CE′ may be spaced apart from the first to third anode electrodes AE1′, AE2′, and AE3′. The cathode electrode CE′ and the first to third anode electrodes AE1′, AE2′, and AE3′ may be disposed at substantially the same height. The cathode electrode CE′ may be spaced apart from the first to third anode electrodes AE1′, AE2′, and AE3′ in the second direction DR2. In embodiments, the cathode electrode CE′ may extend in the first direction DR1 and may be used as a common electrode for the pixel PXL′ and other pixels adjacent to the pixel PXL′. Although not shown, the cathode electrode CE′ extends not only in the first direction DR1 but also in the second direction DR2 and may be used as a common electrode for all of the sub-pixels SP of FIG. 3. As described above, the cathode electrode CE′ may have various shapes.

First to third light emitting elements LD1′, LD2′, and LD3′ may be disposed on the first to third anode electrodes AE1′, AE2′, and AE3′ and the cathode electrode CE′. The first light emitting element LD1′ may be electrically connected to the first anode electrode AE1′ and the cathode electrode CE′. The first light emitting element LD1′ may be provided as the light emitting element LD (see FIG. 2) connected to the sub-pixel circuit SPC (see FIG. 2) of the first sub-pixel SP1′. The second light emitting element LD2′ may be electrically connected to the second anode electrode AE2′ and the cathode electrode CE′. The second light emitting element LD2′ may be provided as the light emitting element LD connected to the sub-pixel circuit SPC of the second sub-pixel SP2′. The third light emitting element LD3′ may be electrically connected to the third anode electrode AE3′ and the cathode electrode CE′. The third light emitting element LD3′ may be provided as the light emitting element LD connected to the sub-pixel circuit SPC of the third sub-pixel SP3′.

The first to third light emitting elements LD1′, LD2′, and LD3′ may be inorganic light emitting diodes including an inorganic light emitting material. However, embodiments are not limited thereto, and for example, organic light emitting diodes may be used.

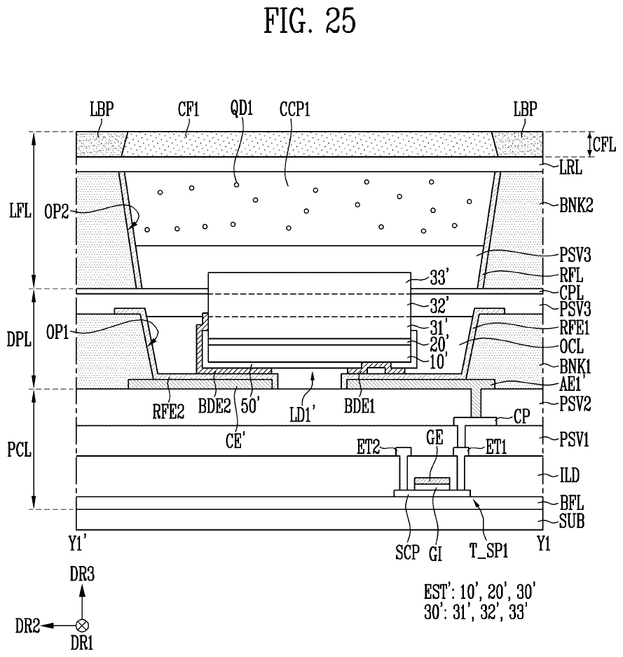

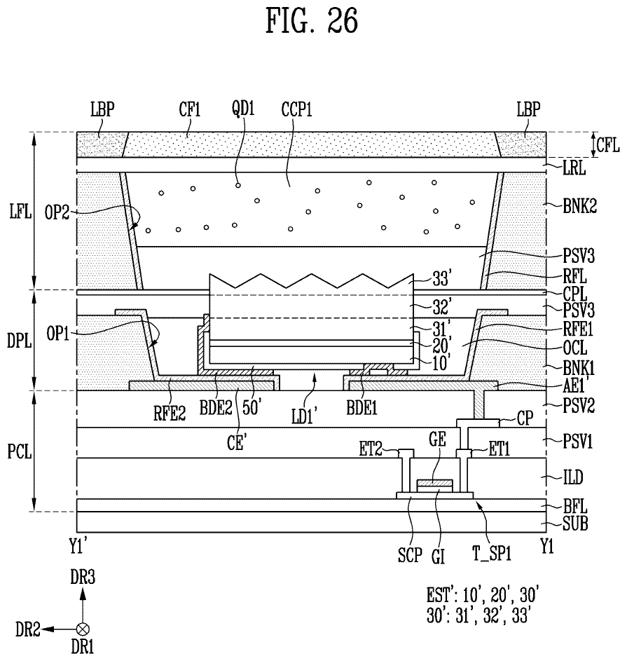

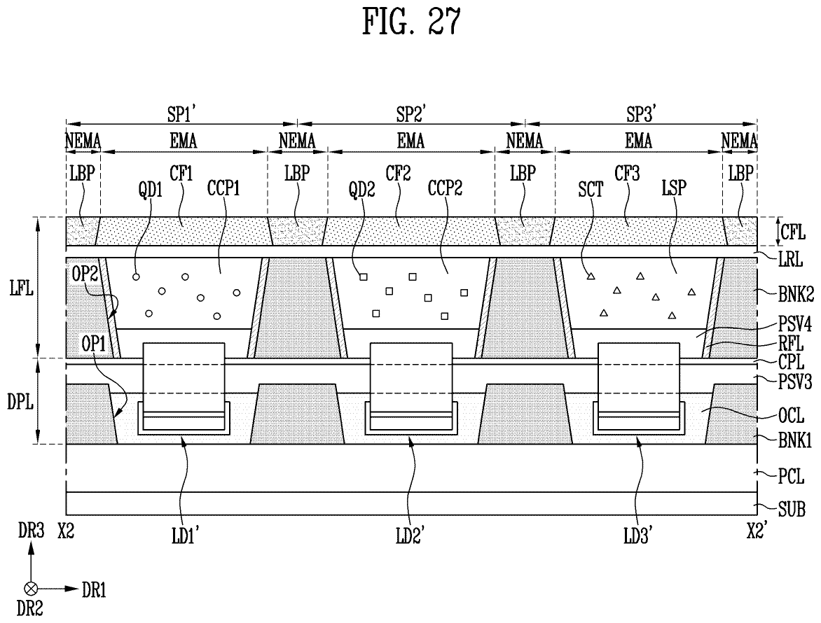

FIGS. 25 to 27 are schematic cross-sectional views illustrating the pixel of FIG. 24. FIGS. 25 and 26 are schematic cross-sectional views taken along line Y1-Y1′ of FIG. 24, and FIG. 27 is a schematic cross-sectional view taken along line X2-X2′ of FIG. 24.

Referring to FIGS. 24 and 25, the pixel circuit layer PCL, the display element layer DPL, and the light functional layer LFL may be sequentially disposed on the substrate SUB.

The pixel circuit layer PCL may be configured substantially the same as that described with reference to FIG. 7. Therefore, a description of an overlapping content is omitted.

The display element layer DPL may be disposed on the pixel circuit layer PCL. The display element layer DPL may include the first anode electrode AE1′, the cathode electrode CE′, the first bank BNK1, first and second reflective electrodes RFE1, RFE2, the first light emitting element LD1′, the overcoat layer OCL, the third passivation layer PSV3, and the capping layer CPL.

The first anode electrode AE1′ and the cathode electrode CE′ may be disposed on the pixel circuit layer PCL.

The first anode electrode AE1′ may be electrically connected to a connection pattern CP through a contact hole passing through the second passivation layer PSV2. As described above, the first anode electrode AE1′ may be electrically connected to the transistor configuring the sub-pixel circuit SPC (see FIG. 2) of the first sub-pixel SP1.

The cathode electrode CE′ may be spaced apart from the first anode electrode AE1′ in the second direction DR2. The cathode electrode CE′ may be electrically connected to the second power voltage node VSSN of FIG. 2. Accordingly, the second power voltage applied to the second power voltage node VSSN may be transmitted to the cathode electrode CE′.

The first bank BNK1 may be disposed on the first anode electrode AE1′ and the cathode electrode CE′. The first bank BNK1 may have a first opening OP1 exposing portions of the first anode electrode AE1′ and the cathode electrode CE′. The first light emitting element LD1′ may be disposed in the first opening OP1 of the first bank BNK1. As described above, the first bank BNK1 may be provided as a pixel defining layer that defines an area where the first light emitting element LD1′ is positioned.

The first bank BNK1 may be configured to include a light blocking material to prevent light mixing between adjacent sub-pixels. In embodiments, the first bank BNK1 may include an organic material. For example, the first bank BNK1 may include an organic insulating material such as acryl resin, epoxy resin, phenol resin, polyamide resin, and polyimide resin.

The first reflective electrode RFE1 may be disposed on an exposed portion of the first anode electrode AE1′ and on a side surface of the first bank BNK1 adjacent thereto. The second reflective electrode RFE2 may be disposed on an exposed portion of the cathode electrode CE′ and on a side surface of the first bank BNK1 adjacent thereto. The first and second reflective electrodes RFE1 and RFE2 may include conductive materials suitable for reflecting light. Accordingly, light output efficiency of the first light emitting element LD1′ may be improved. In embodiments, the first and second reflective electrodes RFE1 and RFE2 may include at least one among aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them. However, embodiments are not limited thereto.

The first light emitting element LD1′ may be electrically connected to the first anode electrode AE1′ through the first reflective electrode RFE1. The first light emitting element LD1′ may be electrically connected to the cathode electrode CE′ through the second reflective electrode RFE2. The first light emitting element LD1′ may be bonded and coupled to the first and second reflective electrodes RFE1 and RFE2.

The first light emitting element LD1′ may include a first bonding electrode BDE1, a second bonding electrode BDE2, an insulating layer 50′, and a light emitting stack EST′. The light emitting stack EST′ may include a first semiconductor layer 10′, an active layer 20′, and a second semiconductor layer 30′ sequentially stacked each other. The first light emitting element LD1′ may be a flip chip type light emitting element.

The first semiconductor layer 10′ may be configured to provide a hole. The first semiconductor layer 10′ may have a first polarity. For example, the first semiconductor layer 10′ may include at least one p-type semiconductor layer. For example, the first semiconductor layer 10′ may include at least one semiconductor material among gallium nitride (GaN), aluminum gallium nitride (AlGaN), indium gallium nitride (InGaN), aluminum nitride (AlN), and indium nitride (InN), and may be a p-type semiconductor layer doped with a first conductive dopant (or a p-type dopant), such as magnesium (Mg), zinc (Zn), calcium (Ca), strontium (Sr), and barium (Ba). However, a material configuring the first semiconductor layer 10′ is not limited thereto, and various other materials may configure the first semiconductor layer 10′. In an embodiment of the disclosure, the first semiconductor layer 10′ may include a gallium nitride (GaN) semiconductor material doped with the first conductive dopant (or the p-type dopant).

The second semiconductor layer 30′ may be disposed on the first semiconductor layer 10′ and may be configured to provide an electron. The second semiconductor layer 30′ may have a second polarity different from the first polarity. For example, the second semiconductor layer 30′ may include at least one n-type semiconductor layer. For example, the second semiconductor layer 30′ may include at least one semiconductor material among gallium nitride (GaN), aluminum gallium nitride (AlGaN), indium gallium nitride (InGaN), aluminum nitride (AlN), and indium nitride (InN), and may be an n-type semiconductor layer doped with a second conductive dopant (or an n-type dopant) such as silicon (Si), germanium (Ge), and tin (Sn). However, a material configuring the second semiconductor layer 30′ is not limited thereto, and various other materials may configure the second semiconductor layer 30′. In an embodiment of the disclosure, the second semiconductor layer 30′ may include a gallium nitride (GaN) semiconductor material doped with the second conductive dopant (or the n-type dopant).

In embodiments, the second semiconductor layer 30′ may include a first doping area 31′, a second doping area 32′, and a third doping area 33′ sequentially in the third direction DR3. The first doping area 31′ may be an area where a dopant is doped at a relatively high concentration, and the third doping area 33′ may be an area where a dopant is not doped substantially or a dopant is doped at a relatively low concentration. The second doping area 32′ may be an area where a dopant is doped at a concentration lower than that of the first doping area 31′ and higher than that of the third doping area 33′.

A first average doping concentration of the dopant doped into the second semiconductor layer 30′ in the first doping area 31′ may be greater than a second average doping concentration of the dopant doped into the second semiconductor layer 30′ in the second doping area 32′. For example, the first average doping concentration may be about 8 times or more than the second average doping concentration. The second average doping concentration of the dopant doped into the second semiconductor layer 30′ in the second doping area 32′ may be greater than a third average doping concentration of the dopant doped into the second semiconductor layer 30′ in the third doping area 33′. For example, the second average doping concentration may be about 8 times or more than the third average doping concentration.

The active layer 20′ may be interposed between the first semiconductor layer 10′ and the second semiconductor layer 30′ and may provide an area where the electron and the hole are recombined. As the electron and the hole recombine in the active layer 20′, the electron and the hole may transit to a lower energy level, and thus light having a wavelength corresponding thereto may be generated. The active layer 20′ may be formed as a single or multiple quantum wells structure. In case that the active layer 20′ is formed as the multiple quantum wells structure, a part including a barrier layer, a strain reinforcing layer, and a well layer may be repeatedly stacked each other to form the active layer 20′. However, the active layer 20′ is not limited to the above-described structure.

The insulating layer 50′ may cover a portion of an outer peripheral surface of the light emitting stack EST′. In this case, the insulating layer 50′ may cover at least a side surface of the active layer 20′. The insulating layer 50′ may serve to prevent an electrical short circuit that may occur when the active layer 20′ contacts a conductive material other than the first and second semiconductor layers 10′ and 30′. The insulating layer 50′ may include a transparent insulating material. The insulating layer 50′ may be configured to expose a portion of a lower surface of the first semiconductor layer 10′ for electrical connection with the first bonding electrode BDE1.

In embodiments, the insulating layer 50′ may be configured to entirely cover an outer peripheral surface of the first semiconductor layer 10′ and an outer peripheral surface of the active layer 20′ and cover a side surface of the second semiconductor layer 30′ in a portion of the first doping area 31′ adjacent to the active layer 20′. In this case, the insulating layer 50′ may be configured so as not to cover the side surface of the second semiconductor layer 30′ in the second and third doping areas 32′ and 33′ and so as not to cover the side surface of the second semiconductor layer 30′ in at least a portion of the first doping area 31′ which is not adjacent to the active layer 20′.

The first bonding electrode BDE1 may be disposed under the first semiconductor layer 10′. The first bonding electrode BDE1 may be electrically connected to the first semiconductor layer 10′ through an open portion exposing a portion of the lower surface of the first semiconductor layer 10′ defined in the insulating layer 50′. In embodiments, the first bonding electrode BDE1 may be disposed on the first anode electrode AE1′ so as to overlap the first anode electrode AE1′. The first bonding electrode BDE1 may be electrically connected to the first anode electrode AE1′. For example, the first bonding electrode BDE1 may be electrically connected to the first anode electrode AE1′ through the first reflective electrode RFE1. The first bonding electrode BDE1 may include a eutectic metal.

The second bonding electrode BDE2 may extend from an upper portion of the insulating layer 50′ covering the lower surface of the first semiconductor layer 10′ and may contact the side surface of the second semiconductor layer 30′ which is not covered by the insulating layer 50′. Accordingly, the second bonding electrode BDE2 may be electrically connected to the second semiconductor layer 30′. In embodiments, the second bonding electrode BDE2 may be disposed on the cathode electrode CE′ so as to overlap the cathode electrode CE′. The second bonding electrode BDE2 may be electrically connected to the cathode electrode CE′. For example, the second bonding electrode BDE2 may be electrically connected to the cathode electrode CE′ through the second reflective electrode RFE2. The second bonding electrode BDE2 may include a eutectic metal.

In embodiments, the second bonding electrode BDE2 may directly contact at least a portion of the side surface of the second semiconductor layer 30′ in the first doping area 31′. For example, the second semiconductor layer 30′ and the reflective electrode layer 60′ may electrically contact each other in the first doping area 31′ where the doping concentration is relatively high. Therefore, efficiency of the first light emitting element LD1′ may be further improved.

In embodiments, the insulating layer 50′ may be interposed between the second bonding electrode BDE2 and the first semiconductor layer 10′, and between the second bonding electrode BDE2 and the active layer 20′. Accordingly, an electrical short circuit that may occur when the second bonding electrode BDE2 contacts the first semiconductor layer 10′ and the active layer 20′ may be prevented.

At least a portion of the second bonding electrode BDE2 may be disposed between the cathode electrode CE′ and the first semiconductor layer 10′. In this case, as described above, the second bonding electrode BDE2 may extend from the upper portion of the insulating layer 50′ and contact the side surface of the second semiconductor layer 30′. Accordingly, for an electrically connection between the second bonding electrode BDE2 and the second semiconductor layer 30′, portions of the first semiconductor layer 10′ and the active layer 20′ may not be removed (for example, mesa-etched or the like). Therefore, in the disclosure, the area of the active layer 20′ that provides a recombination area (e.g., an emission area) of the electron and the hole may be secured as much as possible. For example, the active layer 20′ may completely overlap the second semiconductor layer 30′. In other words, the active layer 20′ and an upper surface of the second semiconductor layer 30′ may have substantially the same planar area.

The overcoat layer OCL may be disposed in the first opening OP1 where the first and second reflective electrodes RFE1 and RFE2 and the first light emitting element LD1′ are disposed. The overcoat layer OCL may fix the first light emitting element LD1′ bonded to the first and second reflective electrodes RFE1 and RFE2 so that the first light emitting element LD1′ does not move. The overcoat layer OCL may protect components disposed under the overcoat layer OCL from a foreign substance such as dust and moisture. For example, the overcoat layer OCL may include at least one of an inorganic insulating layer and an organic insulating layer. For example, the overcoat layer OCL may include epoxy, but embodiments are not limited thereto.

The third passivation layer PSV3 may be disposed on the first bank BNK1 and the overcoat layer OCL. The third passivation layer PSV3 may protect components disposed under the third passivation layer PSV3 and may provide a flat upper surface. The third passivation layer PSV3 and at least one of the first and second passivation layers PSV1 and PSV2 may include substantially the same material, but embodiments are not limited thereto.

In embodiments, the third passivation layer PSV3 may not be disposed on an upper surface of the first light emitting element LD1′. The first light emitting element LD1′ may protrude into the light functional layer LFL. The first light emitting element LD1′ may be positioned at least partially in the second opening OP2 of the second bank BNK2. For example, a height of the upper surface of the first light emitting element LD1′ from the substrate SUB may be higher than that of the lowest end of the reflective layer RFL. Accordingly, light emitted from the first light emitting element LD1′ may be provided to the light functional layer LFL at a relatively high rate.

The capping layer CPL may be disposed on the third passivation layer PSV3. The capping layer CPL may protect components under the capping layer CPL, such as the first light emitting element LD1′, from external water and moisture. In embodiments, the capping layer CPL may not be disposed on the upper surface of the first light emitting element LD1′. In other embodiments, the capping layer CPL may entirely cover the first light emitting element LD1′ and the third passivation layer PSV3. The capping layer CPL may include at least one of metal oxides such as silicon nitride, silicon oxide, silicon oxynitride, and aluminum oxide. However, a material of the capping layer CPL is not limited thereto.

The pixel circuit layer PCL and the display element layer DPL of the first sub-pixel SP1′ are described above. Each of the second and third sub-pixels SP2′ and SP3′ of FIG. 24 may be configured similarly to the first sub-pixel SP1′, unless otherwise described herein.

The light functional layer LFL may be disposed on the capping layer CPL. The light functional layer LFL may include the second bank BNK2, the reflective layer RFL, a fourth passivation layer PSV4, a first light conversion pattern CCP1, the low refractive layer LRL, and the color filter layer CFL.

The second bank BNK2 may be disposed on the capping layer CPL. The second bank BNK2 may overlap the first bank BNK1. The second bank BNK2 may have the second opening OP2 overlapping the first opening OP1.

The second bank BNK2 may be configured to include a light blocking material, thereby preventing light mixing between adjacent sub-pixels. In embodiments, the second bank BNK2 may include an organic material. For example, the second bank BNK2 may include an organic insulating material such as acryl resin, epoxy resin, phenol resin, polyamide resin, and polyimide resin.

The reflective layer RFL may be disposed on side surfaces of the second bank BNK2 adjacent to the second opening OP2. The reflective layer RFL may be configured to reflect incident light, and thus light output efficiency may be improved. The reflective layer RFL may include a material suitable for reflecting light. The reflective layer RFL may include at least one among aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from them. However, embodiments are not limited thereto.

On the capping layer CPL, the fourth passivation layer PSV4 may be disposed in the second opening OP2. The fourth passivation layer PSV4 may protect components disposed under the fourth passivation layer PSV4 and may provide a flat upper surface. The fourth passivation layer PSV4 and at least one of the first to third passivation layers PSV1, PSV2, and PSV3 may include substantially the same material, but embodiments are not limited thereto.

On the fourth passivation layer PSV4, the first light conversion pattern CCP1 may be disposed in the second opening OP2.

The first light conversion pattern CCP1 may include color conversion particles and/or scattering particles. The color conversion particles may change a wavelength of incident light and convert the incident light into light of another color. The color conversion particles may scatter the incident light. In embodiments, the color conversion particles may be quantum dots. The scattering particles may scatter the incident light.

The first sub-pixel SP1′ may be a red sub-pixel. In case that the first light emitting element LD1′ emits light of a blue color, the first light conversion pattern CCP1 may include first color conversion particles QD1 configured to convert the light of the blue color into light of a red color. In case that the first light emitting element LD1′ emits the light of the red color, the first light conversion patterns CCP1 may include scattering particles. As described above, particles included in the first light conversion pattern CCP1 may be variously changed according to a color of light emitted by the first light emitting element LD1′.

The low refractive layer LRL may be disposed on the second bank BNK2, the reflective layer RFL, and the first light conversion pattern CCP1. The low refractive layer LRL may have a refractive index lower than that of the first light conversion pattern CCP1. The low refractive layer LRL may be configured to refract or totally reflect corresponding light according to an incident angle of the light. For example, the low refractive layer LRL may provide light passing through the first light conversion pattern CCP1 back to the first light conversion pattern CCP1. Accordingly, light conversion efficiency of the first light conversion pattern CCP1 may be improved.

The color filter layer CFL may be disposed on the low refractive layer LRL. The color filter layer CFL may include a first color filter CF1 and light blocking patterns LBP. The first color filter CF1 may overlap the first light conversion pattern CCP1. The first color filter CF1 may selectively transmit light of a desired wavelength range. In case that the first sub-pixel SP1′ is a red sub-pixel, the first color filter CF1 may include a red color filter. The light blocking patterns LBP may include at least one of various types of light blocking materials.

Referring to FIGS. 24 and 26, the pixel circuit layer PCL, the display element layer DPL, and the light functional layer LFL may be sequentially disposed on the substrate SUB.

Hereinafter, the disclosure is described based on a difference between the embodiment and the embodiment described with reference to FIGS. 24 and 25, and parts omitted from the description are replaced with the content described above.

In embodiments, an upper surface of the light emitting stack EST′ may have a concave-convex shape. For example, an upper surface of the second semiconductor layer 30′ may have a concavo-convex shape, and the concavo-convex shape may be implemented in the third doping area 33′ of the second semiconductor layer 30′. However, embodiments are not limited thereto, and the concavo-convex shape may be implemented in the second and third doping areas 32′ and 33′ of the second semiconductor layer 30′. As described above, as the upper surface of the light emitting stack EST′ has the concavo-convex shape, light output efficiency of the light emitted from the first light emitting element LD1′ may be improved.

Referring to FIGS. 24, 25, and 27, the pixel circuit layer PCL, the display element layer DPL, and the light functional layer LFL may be sequentially provided on the substrate SUB.

The pixel circuit layer PCL and the display element layer DPL are described similarly to those described with reference to FIG. 25. In the pixel circuit layer PCL, sub-pixel circuits respectively corresponding to the first to third sub-pixels SP1′, SP2′, and SP3′ may be provided. In the display element layer DPL, the first to third light emitting elements LD1′, LD2′, and LD3′ respectively corresponding to the first to third sub-pixels SP1′, SP2′, and SP3′ may be provided. The first to third light emitting elements LD1′, LD2′, and LD3′ may overlap the first openings OP1 of the first bank BNK1. The first light emitting element LD1′ may be connected between the cathode electrode CE′ (see FIG. 25) and a transistor included in a sub-pixel circuit of the first sub-pixel SP1′. The second light emitting element LD2′ may be connected between the cathode electrode CE′ and a transistor included in a sub-pixel circuit of the second sub-pixel SP2′. The third light emitting element LD3′ may be connected between the cathode electrode CE′ and a transistor included in a sub-pixel circuit of the third sub-pixel SP3′. Hereinafter, a description of an overlapping content is omitted.

The light functional layer LFL may be provided on the display element layer DPL. The light functional layer LFL is described similarly to that described with reference to FIG. 25. Hereinafter, a description of an overlapping content is omitted.

The second bank BNK2 may have the second openings OP2. It may be understood that an emission area EMA and a non-emission area NEMA for the first to third sub-pixels SP1′, SP2′, and SP3′ are defined by the second bank BNK2. An area overlapping the second bank BNK2 may correspond to the non-emission area NEMA. An area overlapping the second openings OP2 of the second bank BNK2 may correspond to the emission area EMA of the first to third sub-pixels SP1′, SP2′, and SP3′.

On the capping layer CPL, the fourth passivation layer PSV4 may be disposed in the second openings OP2. On the fourth passivation layer PSV4, the first and second light conversion patterns CCP1 and CCP2 and the light scattering pattern LSP may be disposed in the second openings OP2.

In embodiments, the first to third light emitting elements LD1′, LD2′, and LD3′ may be configured to emit light of a blue color. In this case, the first light conversion pattern CCP1 may include first color conversion particles QD1 configured to convert the light of the blue color into light of a red color. The second light conversion pattern CCP2 may include second color conversion particles QD2 configured to convert the light of the blue color into light of a green color. The light scattering pattern LSP may include scattering particles SCT that scatter the light of the blue color to improve light output efficiency. Accordingly, the first to third sub-pixels SP1′, SP2′, and SP3′ may be provided as a red sub-pixel, a green sub-pixel, and a blue sub-pixel, respectively. In embodiments, at least one of the first and second light conversion patterns CCP1 and CCP2 and the light scattering pattern LSP may further include color conversion particles that convert the light of the blue color into light of a white color.

In embodiments, the first to third light emitting elements LD1′, LD2′, and LD3′ may be configured to emit the light of the red color, the green color, and the blue color, respectively. In this case, each of the first and second light conversion patterns CCP1 and CCP2 and the light scattering pattern LSP may include scattering particles SCT. As described above, according to a color of light emitted from the first to third light emitting elements LD1′, LD2′, and LD3′, particles included in the first and second light conversion patterns CCP1 and CCP2 and the light scattering pattern LSP may be variously changed.

In embodiments, the first and second light conversion patterns CCP1 and CCP2 and the light scattering pattern LSP may be omitted.

The low refractive layer LRL may be disposed on the second bank BNK2, the reflective layer RFL, the first and second light conversion patterns CCP1 and CCP2, and the light scattering pattern LSP. The low refractive layer LRL may have a refractive index lower than that of the first and second light conversion patterns CCP1 and CCP2 and the light scattering pattern LSP. In embodiments, the low refractive layer LRL may be omitted in an area corresponding to the third sub-pixel SP3′.

The color filter layer CFL may be disposed on the low refractive layer LRL. The color filter layer CFL may include first to third color filters CF1, CF2, and CF3, and light blocking patterns LBP.

The first to third color filters CF1, CF2, and CF3 may overlap the first and second light conversion patterns CCP1 and CCP2 and the light scattering pattern LSP, respectively. Each of the first to third color filters CF1, CF2, and CF3 may selectively transmit light of a desired wavelength range. In case that the first sub-pixel SP1′ is a red sub-pixel, the first color filter CF1 may include a red color filter. In case that the second sub-pixel SP2′ is a green sub-pixel, the second color filter CF2 may include a green color filter. In case that the third sub-pixel SP3′ is a blue sub-pixel, the third color filter CF3 may include a blue color filter. The first to third color filters CF1, CF2, and CF3 may have a refractive index higher than that of the low refractive layer LRL. However, embodiments are not limited thereto, and the first to third color filters CF1, CF2, and CF3 may have a refractive index lower than or equal to that of the low refractive layer LRL.

The light blocking patterns LBP may be disposed between the first to third color filters CF1, CF2, and CF3. It may be understood that the emission area (or a light output area) EMA and the non-emission area NEMA for the first to third sub-pixels SP1′, SP2′, and SP3′ are defined by the light blocking patterns LBP. An area overlapping the light blocking patterns LBP may correspond to the non-emission area NEMA. An area that does not overlap the light blocking patterns LBP may correspond to the emission area EMA.

In embodiments, the light blocking patterns LBP may include at least one of various types of light blocking materials. In embodiments, each of the light blocking patterns LBP may be provided in a form of multiple layers in which at least two color filters among the first to third color filters CF1, CF2, and CF3 overlap each other. For example, each of the light blocking patterns LBP may be formed by overlapping the first to third color filters CF1, CF2, and CF3 each other. As another example, a light blocking pattern between the first and second color filters CF1 and CF2 among the light blocking patterns LBP may be formed as multiple layers in which the first and second color filters CF1 and CF2 overlap each other, and a light blocking pattern between the second and third color filters CF2 and CF3 among the light blocking patterns LBP may be formed as multiple layers in which the second and third color filters CF2 and CF3 overlap each other. A light blocking pattern between the first color filter CF1 and the third color filter CF3 of a neighboring pixel may be formed as multiple layers in which the first and third color filters CF1 and CF3 overlap each other. As described above, each of the first to third color filters CF1, CF2, and CF3 may extend to the non-emission area NEMA to form the light blocking patterns LBP.

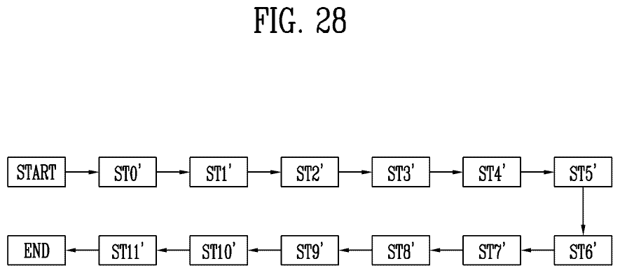

FIGS. 28 to 40 are schematic diagrams illustrating a method of manufacturing a light emitting element included in the pixel of FIG. 25.

Referring to FIG. 28, a preparation step ST0′ and first to eleventh steps ST1′, ST2′, ST3′, ST4′, ST5′, ST6′, ST7′, ST8′, ST9′, ST10′, and ST11′ may be performed.

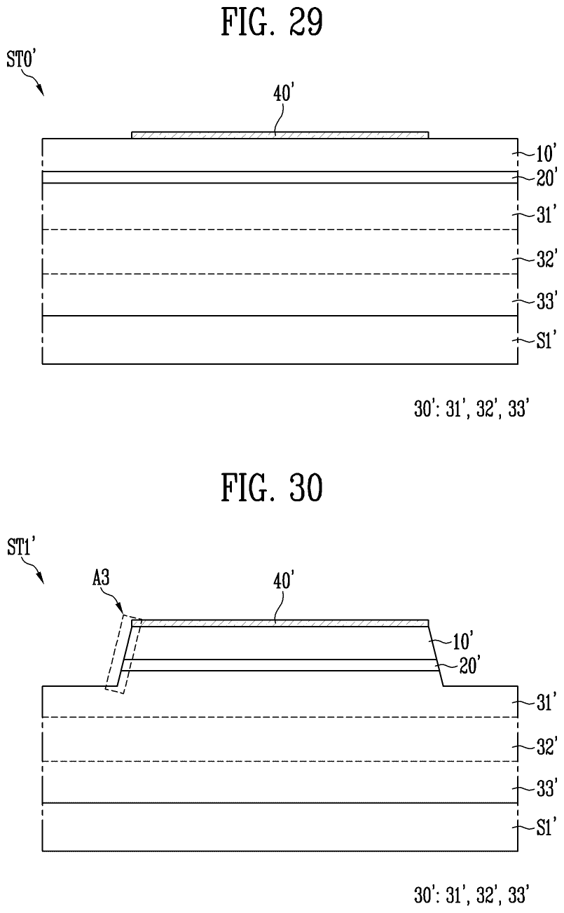

Referring to FIG. 29, after sequentially forming the second semiconductor layer 30′, the active layer 20′, and the first semiconductor layer 10′ on a substrate S1′, an auxiliary electrode 40′ may be formed on the first semiconductor layer 10′ (ST0′).

The substrate S1′ may be, for example, a sapphire substrate. In embodiments, a surface of the substrate S1′ facing the second semiconductor layer 30′ may be substantially flat. In another embodiment, in case that an upper surface of a light emitting element has a concavo-convex shape, the substrate S1 described with reference to FIG. 10 or the like may be used instead of the substrate S1′.

A method of forming the second semiconductor layer 30′, the active layer 20′, and the first semiconductor layer 10′ on the substrate S1′ is not limited. For example, an epitaxial process for sequentially forming the second semiconductor layer 30′, the active layer 20′, and the first semiconductor layer 10′ may be performed.

In this case, the second semiconductor layer 30′ may include the first doping area 31′, the second doping area 32′, and the third doping area 33′. The first to third doping areas 31′, 32′, and 33′ may be formed, for example, by varying a doping concentration of a dopant when performing the epitaxial process.

Referring to FIG. 30, the first semiconductor layer 10′, the active layer 20′, and the second semiconductor layer 30′ may be firstly etched using the auxiliary electrode 40′ as a mask (ST1′).

In embodiments, the first etching may be dry etching. Accordingly, a third surface A3 defined by removing the first semiconductor layer 10′, the active layer 20′, and the second semiconductor layer 30′ through the first etching may be provided as an inclined surface.

In embodiments, only a portion of the first doping area 31′ of the second semiconductor layer 30′ may be removed by the first etching.

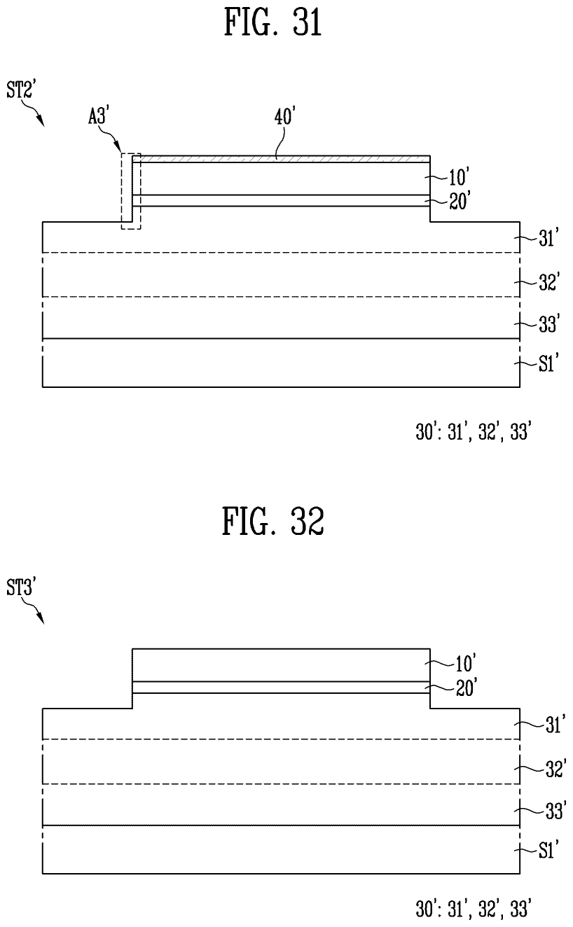

Referring to FIG. 31, the first semiconductor layer 10′, the active layer 20′, and the second semiconductor layer 30′ may be secondly etched using the auxiliary electrode 40′ as a mask (ST2′).

In embodiments, the second etching may be wet etching. Accordingly, the first semiconductor layer 10′, the active layer 20′, and the second semiconductor layer 30′ may be additionally removed by the second etching, and thus a third surface A3′ in which an inclination of the third surface A3 (see FIG. 30) is removed may be provided.

Referring to FIG. 32, selectively, the auxiliary electrode 40′ may be removed (ST3′). A method of removing the auxiliary electrode 40′ is not limited, and various known methods may be used.

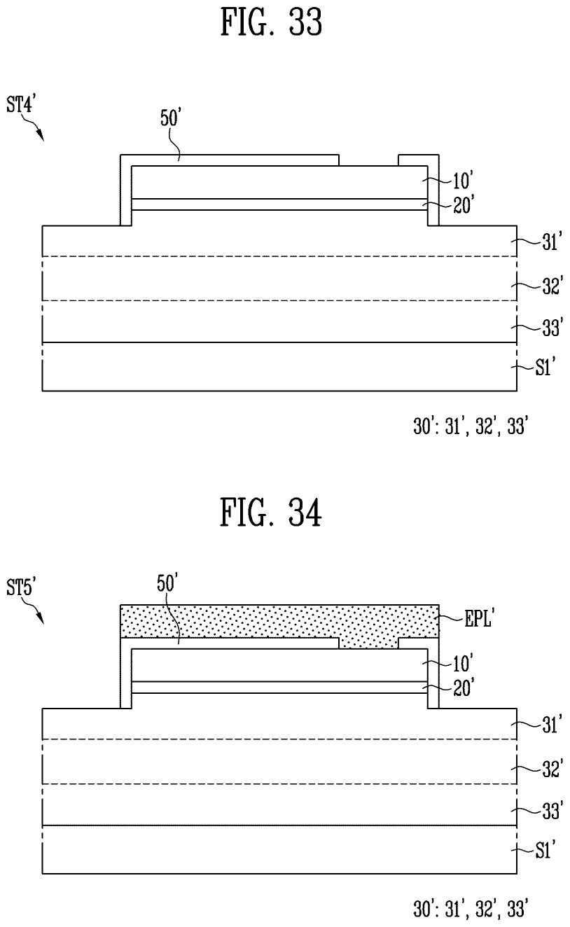

Referring to FIG. 33, the insulating layer 50′ may be formed (ST4′). The insulating layer 50′ may be appropriately patterned. Accordingly, the insulating layer 50′ may entirely cover the third surface A3′ (see FIG. 31) and may define an open portion exposing a portion of the first semiconductor layer 10′.

Referring to FIG. 34, an etch protective layer EPL′ may be formed to cover the insulating layer 50′ covering the first semiconductor layer 10′ and the first semiconductor layer 10′ exposed without being covered by the insulating layer 50′ (ST5′). The etch protective layer EPL′ may serve to prevent components disposed under the etch protective layer EPL′ from being etched by third etching to be described below.

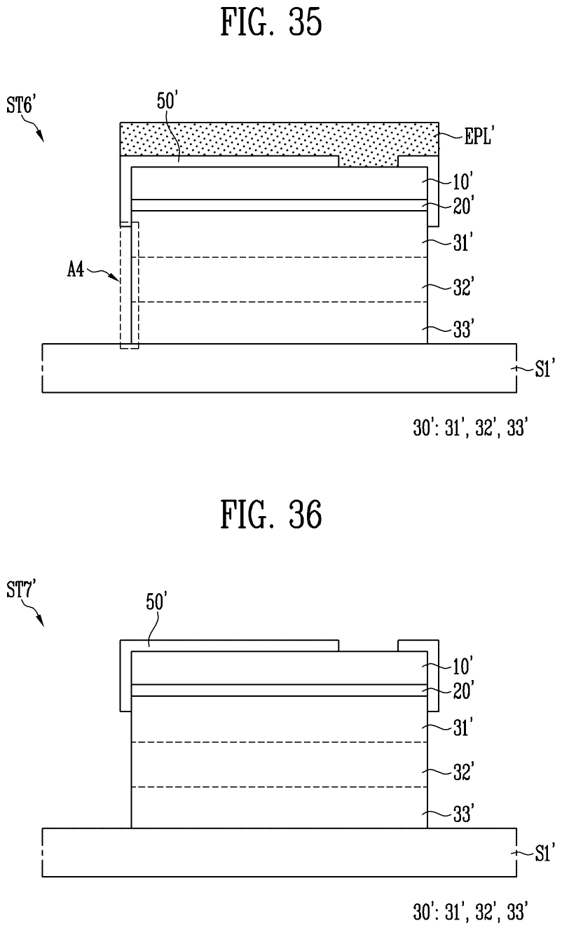

Referring to FIG. 35, the second semiconductor layer 30′ may be thirdly etched using the etch protective layer EPL′ as a mask (ST6′).

In embodiments, the third etching may include dry etching and wet etching performed after the dry etching. Accordingly, a fourth surface A4 defined by removing the second semiconductor layer 30′ through the third etching may be a flat surface where an inclination is removed.

In embodiments, the first to third doping areas 31′, 32′, and 33′ of the second semiconductor layer 30′ may be removed by the third etching, and thus the substrate S1′ may be exposed.

Referring to FIG. 36, the etch protective layer EPL′ may be removed (ST7′).

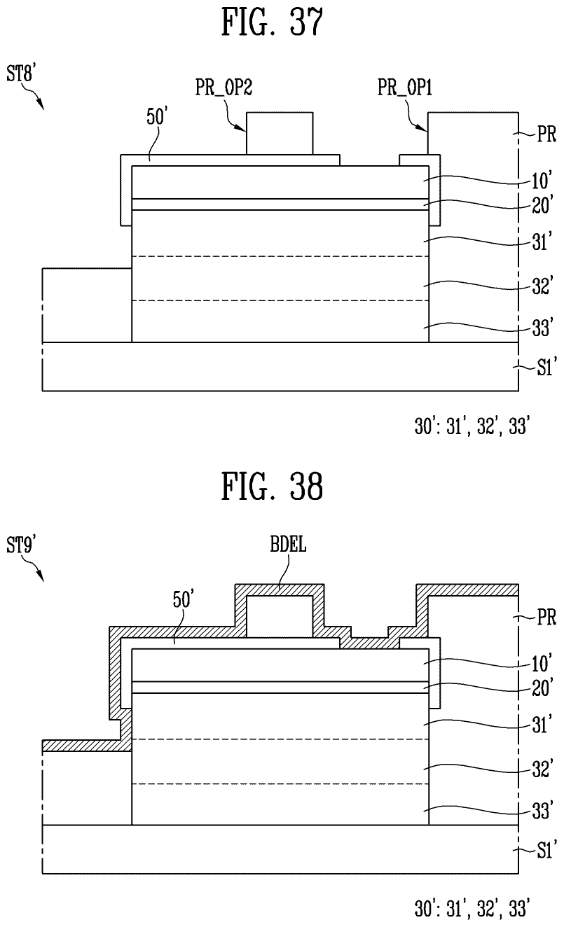

Referring to FIG. 37, a photoresist layer PR may be formed (ST8′). The photoresist layer PR may be appropriately patterned. Accordingly, the open portion defined in the insulating layer 50′ and exposing a portion of the first semiconductor layer 10′, and a first opening PR_OP1 exposing a portion of the insulating layer 50′ adjacent to the open portion may be defined in the photoresist layer PR. A second opening PR_OP2 exposing the insulating layer 50′ and at least a portion of the side surface of the second semiconductor layer 30′ in an area adjacent to the insulating layer 50′ may be defined in the photoresist layer PR. In this case, a portion of the side surface of the second semiconductor layer 30′ exposed by the second opening PR_OP2 may be configured to include at least a portion of the first doping area 31′.

Referring to FIG. 38, a bonding electrode layer BDEL may be formed by isotropic deposition (ST9′). As the bonding electrode layer BDEL is formed by the isotropic deposition, the bonding electrode layer BDEL may be formed along a profile of the photoresist layer PR and components exposed by the first and second openings PR_OP1 and PR_OP2 defined the photoresist layer PR.

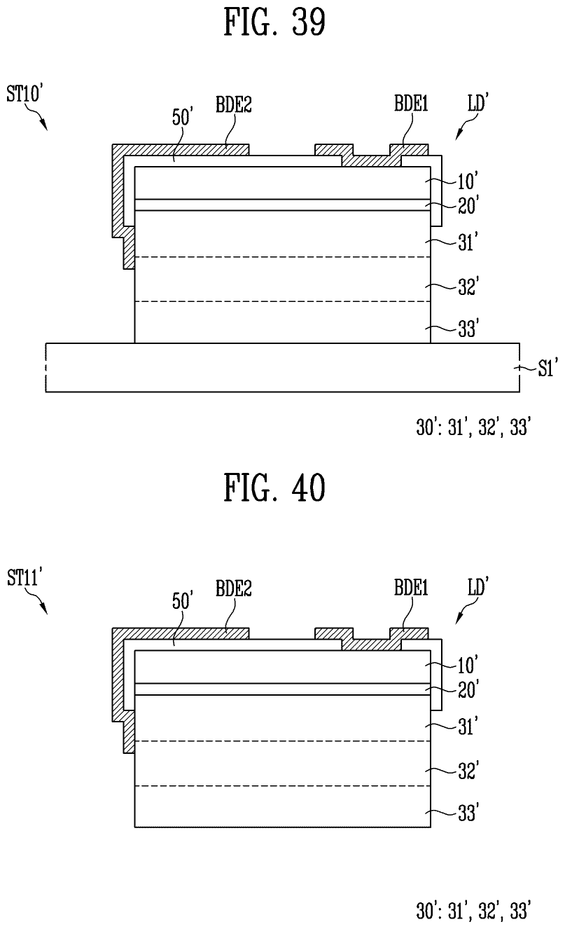

Referring to FIG. 39, the photoresist layer PR may be removed (ST10′). Accordingly, a portion of the bonding electrode layer BDEL covering the photoresist layer PR may be removed, and remaining portions of the bonding electrode layer BDEL which are not removed may form the first bonding electrode BDE1 and the second bonding electrode BDE2.

Referring to FIG. 40, the light emitting element LD′ may be separated from the substrate S1′ (ST11′). For example, a laser or the like may be irradiated to a boundary between the light emitting element LD′ and the substrate S1′. The separated light emitting element LD′ may be provided on the pixel circuit layer PCL described with reference to FIGS. 25 and 27, by using various known transfer means (or methods).

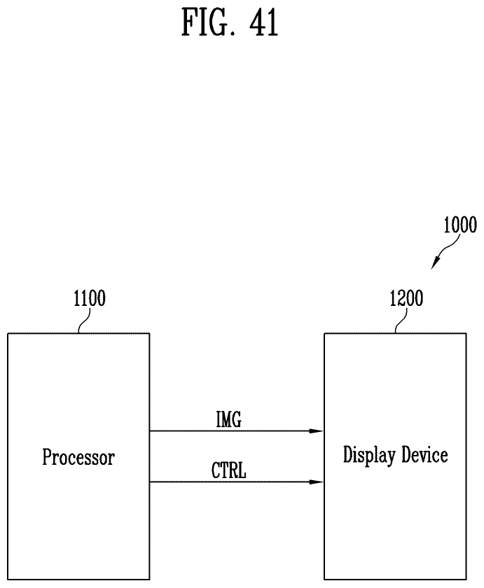

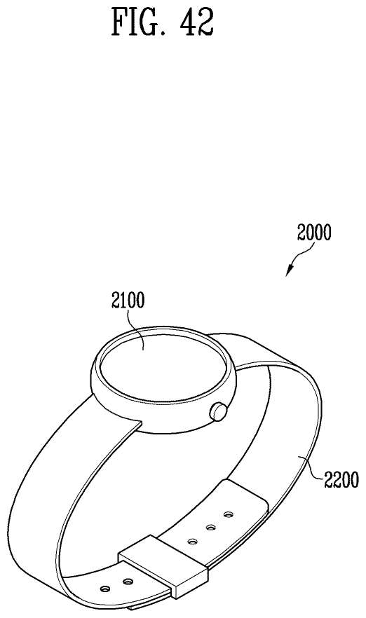

FIG. 41 is a schematic block diagram illustrating a display system according to an embodiment.

Referring to FIG. 41, the display system 1000 may include a processor 1100 and a display device 1200.

The processor 1100 may perform various tasks and calculations. In embodiments, the processor 1100 may include an application processor, a graphics processor, a microprocessor, a central processing unit (CPU), and the like. The processor 1100 may be connected to other components of the display system 1000 through a bus system to control the other components.

The processor 1100 may transmit image data IMG and a control signal CTRL to the display device 1200. The display device 1200 may display an image based on the image data IMG and the control signal CTRL. The display device 1200 may be configured similarly to the display device DD described with reference to FIG. 1. In this case, the image data IMG and the control signal CTRL may be provided as the input image data IMG and the control signal CTRL of FIG. 1, respectively.

The display system 1000 may include a computing system providing an image display function, such as a smart watch, a mobile phone, a smart phone, a portable computer, a tablet personal computer (PC), a watch phone, an automotive display, smart glasses, a portable multimedia player (PMP), a navigation device, and an ultra mobile personal computer (UMPC). The display system 1000 may include at least one of a head-mounted display (HMD) device, a virtual reality (VR) device, a mixed reality (MR) device, and an augmented reality (AR) device.

FIGS. 42 to 45 are schematic views illustrating application examples of the display system of FIG. 41.

Referring to FIG. 42, the display system 1000 of FIG. 41 may be applied to a smart watch 2000 including a display part 2100 and a strap part 2200.

The smart watch 2000 may be a wearable electronic device. For example, the smart watch 2000 may have a structure in which the strap part 2200 is mounted on a user's wrist. Here, the display system 1000 and/or the display device 1200 may be applied to the display part 2100, and image data including time information may be provided to a user.

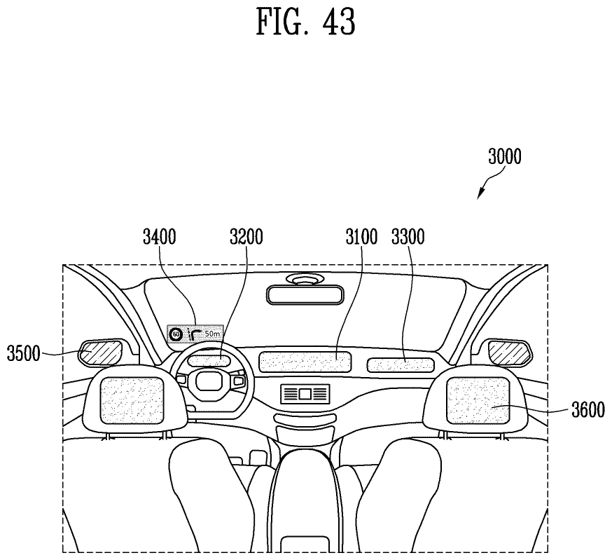

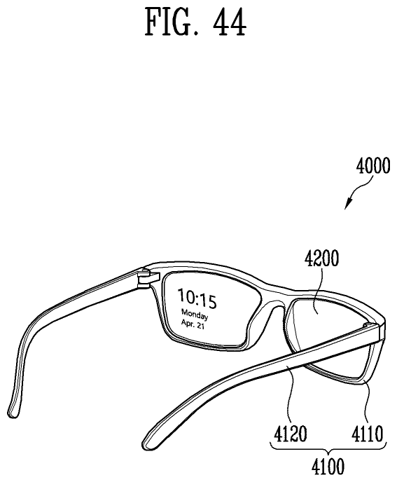

Referring to FIG. 43, the display system 1000 of FIG. 41 may be applied to an automotive display system 3000. Here, the automotive display system 3000 may include a computing system provided inside and/or outside a vehicle to provide image data.

For example, the display system 1000 and/or the display device 1200 may be applied to at least one of an infotainment panel 3100, a cluster 3200, a co-driver display 3300, a head-up display 3400, a rear-view mirror display 3500, and a rear seat display 3600 provided in a vehicle.

Referring to FIG. 44, the display system 1000 of FIG. 41 may be applied to smart glasses 4000. The smart glasses 4000 may be a wearable electronic device that may be worn on a user's head. For example, the smart glasses 4000 may be a wearable device for augmented reality.

The smart glasses 4000 may include a frame 4100 and a lens part 4200. The frame 4100 may include a housing 4110 that supports the lens part 4200 and a leg part 4120 for the user to wear. The leg part 4120 may be extended to the housing 4110 through a hinge and may be folded or unfolded relative to the housing 4110.

A battery, a touch pad, a microphone, a camera, and the like may be built in the frame 4100. A projector that outputs light, a processor that controls a light signal, and the like may be built in the frame 4100.

The lens part 4200 may include an optical member that transmits or reflects light. For example, the lens part 4200 may include glass, transparent synthetic resin, or the like.

In order for user's eyes to recognize visual information, the lens part 4200 may reflect an image by the light signal transmitted from the projector of the frame 4100 by a rear surface (for example, a surface in a direction in which the lens part 4200 faces the user's eyes) of the lens part 4200. For example, the user may recognize visual information such as time and date displayed on the lens part 4200. In this case, the projector and/or the lens part 4200 may be a type of display device. The display device 1200 may be applied to the projector and/or the lens part 4200.

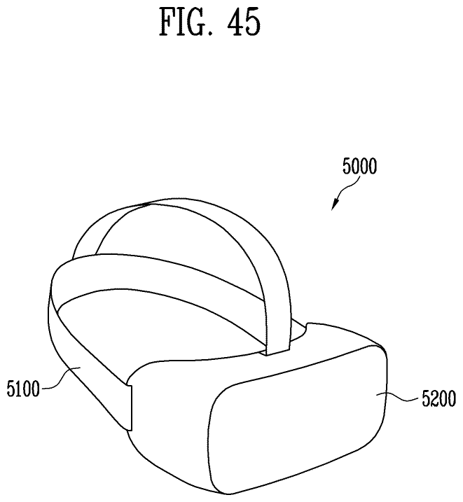

Referring to FIG. 45, the display system 1000 of FIG. 41 may be applied to a head-mounted display device 500.

The head-mounted display device 5000 may be a wearable electronic device that may be worn on a user's head. For example, the head-mounted display device 5000 may be a wearable device for virtual reality or mixed reality.

The head-mounted display device 5000 may include a head mount band 5100 and a display device receiving case 5200. The head mount band 5100 may be extended to the display device receiving case 5200. The head mount band 5100 may include a horizontal band and/or a vertical band for fixing the head-mounted display device 5000 to a user's head. The horizontal band may be configured to surround a side portion of the user's head, and the vertical band may be configured to surround an upper portion of the user's head. However, embodiments are not limited thereto. For example, the head mount band 5100 may be implemented in a form of a glasses frame, a helmet, or the like.

The display device receiving case 5200 may receive the display system 1000 and/or the display device 1200.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
an anode electrode;
a light emitting element disposed on the anode electrode; and
a cathode electrode covering at least an upper surface of the light emitting element, wherein
the light emitting element comprises:
a bonding electrode electrically connected to the anode electrode;
a light emitting stack disposed on the bonding electrode and including a first semiconductor layer, a second semiconductor layer disposed on the first semiconductor layer, and an active layer disposed between the first semiconductor layer and the second semiconductor layer;
an insulating layer covering at least a side surface of the active layer; and
a reflective electrode layer covering a side surface of the second semiconductor layer which is not covered by the insulating layer, and
the reflective electrode layer electrically contacts the cathode electrode.

2. The display device according to claim 1, wherein
the side surface of the second semiconductor layer which is not covered by the insulating layer has an inverse taper shape, and
a width of the inverse taper shape gradually increases in a direction away from the anode electrode.

3. The display device according to claim 1, wherein
the second semiconductor layer includes a first area adjacent to the active layer and a second area on the first area, and
the reflective electrode layer covers the side surface of the second semiconductor layer in the second area.

4. The display device according to claim 3, wherein the insulating layer covers the side surface of the second semiconductor layer in the first area.

5. The display device according to claim 1, wherein
the second semiconductor layer includes a first doping area, a second doping area, and a third doping area sequentially in a direction away from the anode electrode, and
a first average doping concentration in the first doping area is greater than a second average doping concentration in the second doping area.

6. The display device according to claim 5, wherein the second average doping concentration in the second doping area is greater than a third average doping concentration in the third doping area.

7. The display device according to claim 5, wherein the reflective electrode layer directly contacts at least a portion of the side surface of the second semiconductor layer in the first doping area.

8. The display device according to claim 1, wherein the reflective electrode layer does not cover an upper surface of the light emitting stack.

9. The display device according to claim 1, wherein the reflective electrode layer includes at least one selected from a group consisting of aluminum (Al), titanium (Ti), and chromium (Cr).

10. The display device according to claim 1, wherein the upper surface of the light emitting stack has a concavo-convex shape.

11. The display device according to claim 1, wherein the reflective electrode layer further covers at least a portion of the insulating layer.

12. A display device comprising:
an anode electrode;
a cathode electrode spaced apart from the anode electrode; and
a light emitting element disposed on the anode electrode and the cathode electrode,
wherein the light emitting element comprises:
a light emitting stack including a first semiconductor layer, a second semiconductor layer disposed on the first semiconductor layer, and an active layer disposed between the first semiconductor layer and the second semiconductor layer;
an insulating layer covering at least a side surface of the active layer;
a first bonding electrode electrically connected to each of the first semiconductor layer and the anode electrode; and
a second bonding electrode extending from the insulating layer covering a lower surface of the first semiconductor layer, contacting a side surface of the second semiconductor layer which is not covered by the insulating layer, and electrically connected to the cathode electrode.

13. The display device according to claim 12, wherein the active layer completely overlaps the second semiconductor layer.

14. The display device according to claim 12, wherein
the second semiconductor layer includes a first doping area, a second doping area, and a third doping area sequentially in a direction away from the anode electrode, and
a first average doping concentration in the first doping area is greater than a second average doping concentration in the second doping area.

15. The display device according to claim 14, wherein the second average doping concentration in the second doping area is greater than a third average doping concentration in the third doping area.

16. The display device according to claim 14, wherein the second bonding electrode directly contacts at least a portion of the side surface of the second semiconductor layer in the first doping area.

17. The display device according to claim 12, wherein the insulating layer is disposed between the second bonding electrode and the first semiconductor layer.

18. The display device according to claim 12, wherein an upper surface of the light emitting stack has a concavo-convex shape.

19. The display device according to claim 12, wherein
the insulating layer entirely covers a side surface of the first semiconductor layer and the lower surface of the first semiconductor layer, and defines an open portion exposing a portion of the lower surface of the first semiconductor layer, and
the first bonding electrode is electrically connected to the lower surface of the first semiconductor layer through the open portion.

20. The display device according to claim 12, wherein
the first bonding electrode overlaps the anode electrode, and
the second bonding electrode overlaps the cathode electrode.

21. An electronic device, comprising:
a processor to provide input image data; and
a display device to display an image based on the input image data, wherein
the display device comprises:
an anode electrode;
a light emitting element disposed on the anode electrode; and
a cathode electrode covering at least an upper surface of the light emitting element, wherein
the light emitting element comprises:
a bonding electrode electrically connected to the anode electrode;
a light emitting stack disposed on the bonding electrode and including a first semiconductor layer, a second semiconductor layer disposed on the first semiconductor layer, and an active layer disposed between the first semiconductor layer and the second semiconductor layer;
an insulating layer covering at least a side surface of the active layer; and
a reflective electrode layer covering a side surface of the second semiconductor layer which is not covered by the insulating layer, and
the reflective electrode layer electrically contacts the cathode electrode.
